(19) United States
(12) Patent Application Publication
(10) Pub. No.: US 2002/0113268 A1
(43) Pub. Date: Aug. 22, 2002

(54) Nonvolatile memory, semiconductor device and method of manufacturing the same

(76) Inventors: Jun Koyama, Kanagawa (JP); Kiyoshi Kato, Kanagawa (JP)

Correspondence Address: NIXON PEABODY, LLP, 8180 GREENSBORO DRIVE, SUITE 800, MCLEAN, VA, 22102, US

(21) Appl. No.: 09/774,888

(22) Filed: Feb. 1, 2001

(30) Foreign Application Priority Data
Feb. 1, 2000 (JP) 2000-023656

(51) Int. Cl. H01L 23/62

(52) U.S. Cl. 257/359

(57) ABSTRACT

The present invention provides a nonvolatile memory that can be integrally formed with other semiconductor devices and can be reduced in size. A memory TFT, a switching TFT and other peripheral circuits constituting a nonvolatile memory are integrally formed on a substrate by TFTs. The memory TFT and the switching TFT are formed on the same semiconductor active layer, and a semiconductor active layer of the memory TFT is formed thinner than semiconductor active layers of the other TFTs. As a result, a nonvolatile memory that is hardly deteriorated and that can be reduced in size is provided, in which writing/erasing for the memory TFT can be realized at a low voltage.

### BACKGROUND OF THE INVENTION

1. Field of the invention

The present invention relates to a nonvolatile memory including thin-film transistors (hereinafter, abbreviated as TFTs) formed by using an SOI (Silicon On Insulator) technique and a method of manufacturing the same. Particularly, the present invention relates to a nonvolatile memory integrally formed with peripheral circuits such as a driver circuit on a substrate having an insulating surface, particularly, to an EEPROM (Electrically Erasable and Programmable Read Only Memory). Moreover, the present invention also relates to a semiconductor device including a nonvolatile memory integrally formed with an arbitrary circuit including TFTs on a substrate having an insulating surface.

In the specification, the term semiconductor device generically indicates the devices that function by taking advantage of semiconductor properties; for example, electro-optical devices as represented by a liquid crystal display device and an EL display device, and electronic apparatus including such an electro-optical device are all included in the category of the semiconductor device.

2. Description of the Related Art

Recently, a semiconductor device having an increased number of functions, enhanced functions and smaller size has been rapidly developed. With this trend, a memory is more and more frequently used in various semiconductor devices. In view of such a demand, a small-size memory having high performance, a large amount of a memory capacity and high reliability is required.

At present, a magnetic disk and a semiconductor nonvolatile memory made of bulk silicon are the most frequently used as a memory device for a semiconductor device.

The magnetic disk is one of the memory devices having the largest memory capacity used for a semiconductor device. However, the magnetic disk has drawbacks such as a difficulty in reduction of size and low writing/reading speed.

On the other hand, although the semiconductor nonvolatile memory is inferior to the magnetic disk in terms of the memory capacity, its writing/reading speed is dozens of times higher than that of the magnetic disk. Moreover, the semiconductor nonvolatile memory having sufficient performance in terms of the number of rewrites and data holding time has been developed. In such a context, there is a growing tendency toward the use of the semiconductor memory in place of the magnetic disk.

A conventional semiconductor nonvolatile memory is manufactured by using bulk silicon and is enclosed in a package. Therefore, in the case where such a semiconductor nonvolatile memory is to be mounted on a semiconductor device, the number of fabrication steps increases and its package size prevents the reduction of the semiconductor device in size.

### SUMMARY OF THE INVENTION

The present invention is devised in view of the above problems, and therefore has an object to provide a nonvolatile memory which can be integrally formed with other components of a semiconductor device and can be reduced in size. Moreover, the present invention has another object of the invention to provide a semiconductor device including a nonvolatile memory, which can be reduced in size.

As means of achieving the above proposes, a nonvolatile memory is constituted by using TFTs which are formed using a SOI technique in the present invention.

According to the present invention, a nonvolatile memory can be integrally formed with an arbitrary circuit constituted by using TFTs on an insulating substrate. Particularly, a memory cell, its driver circuit (typically, an address decoder) and other peripheral circuits are integrally formed on an insulating, substrate, thereby making it possible to provide a nonvolatile memory which can be reduced in size. Furthermore, an arbitrary circuit including TFTs that constitutes another semiconductor device is integrally formed on an insulating substrate, thereby making it possible to provide a semiconductor device including a nonvolatile memory, which can be reduced in size.

Specifically, a nonvolatile memory according to the present invention includes a memory cell array in which memory cells are arranged in matrix, each memory cell consisting of a memory TFT and a switching TFT. Moreover, the non-volatile memory may include a driver circuit of the memory cell and other peripheral circuits.

In the present invention, semiconductor active layers of the memory TFT and the switching TFT are continuously formed. In other words, the memory TFT and the switching TFT constituting each memory cell are formed on the same semiconductor active layer. With such a structure, the area of the memory cell can be reduced as compared with the case where the memory TFT and the switching TFT constituting each memory cell are formed on different semiconductor active layers.

The semiconductor active layer of the memory TFT is formed thinner than that of the switching active layer, or is formed to have a thickness in the range of 1 to 100 nm (preferably 1 to 50 nm, more preferably 10 to 40 nm). The semiconductor active layer of the memory TFT is formed thin in this way, thereby allowing efficient writing as compared with the semiconductor active layer having a thicker thickness. This also signifies that writing can be performed at a lower driving voltage. At the same time, the memory cell has such a structure that can support an increased number of writings.

The manufacture steps of a nonvolatile memory according, to the present invention includes the step of forming a first amorphous semiconductor layer and a second amorphous semiconductor layer on an insulating substrate; and the step of crystallizing these amorphous semiconductor layers to form a crystalline semiconductor layer including a region having a first thickness and a region having a second thickness.

In the thus formed crystalline semiconductor layer, a memory TFT including the region having the first thickness as a semiconductor active layer and a switching TFT including the region having the second thickness as a semiconductor active layer are formed, thereby making it possible to manufacture a nonvolatile memory having a memory cell in which the semiconductor active layers of the memory TFT and the switching TFT are continuously formed. Furthermore, the semiconductor active layers are formed so that the first thickness is thinner than the second thickness, or the first thickness is 1 to 100 nm (preferably, 1 to 50 nm, more preferably, 10 to 40 nm), thereby allowing the manufacture of a nonvolatile memory according to the present invention.

The structure according to the present invention will be described below.

The present invention provides a nonvolatile memory including at least a memory cell array in which memory cells are arranged in matrix, each of the memory cells consisting of a memory TFT and a switching TFT, wherein:

the memory TFT includes at least a semiconductor active layer, a first insulating film, a floating gate electrode, a second insulating film and a control ,ate electrode, which are formed on an insulating substrate;

the switching TFT includes at least a semiconductor active layer, a gate insulating film and a gate electrode, which are formed on the insulating substrate;

wherein the memory TFT and the switching TFT are integrally formed on the insulating substrate;

the semiconductor active layer of the memory TFT and the semiconductor active layer of the switching TFT are continuous; and

a thickness of the semiconductor active layer of the memory TFT is thinner than that of the semiconductor active layer of the switching TFT.

It is preferable that the thicknesses of the semiconductor active layers of the memory TFT and the switching TFT are 1 to 150 nm.

The present invention provides a nonvolatile memory in which memory cells are arranged in matrix, each of the memory cells consisting of a memory TFT and a switching TFT, wherein:

the memory TFT includes at least a semiconductor active layer, a first insulating film, a floating gate electrode, a second insulating film and a control gate electrode, which are formed on an insulating substrate;

the switching TFT includes at least a semiconductor active layer, a gate insulating film and a gate electrode, which are formed on the insulating, substrate,;

the memory TFT and the switching TFT are integrally formed on the insulating substrate,

the semiconductor active layer of the memory TFT and the semiconductor active layer of the switching TFT are continuous, and

a thickness of the semiconductor active layer of the memory TFT is 1 to 100 nm, and a thickness of the semiconductor active layer of the switching TFT is 1 to 150 nm.

It is preferable that a thickness of the semiconductor active layer of the memory TFT is 1 to 50 nm and that a thickness of the semiconductor active layer of the switching TFT is 10 to 100 nm It is more preferable that a thickness of the semiconductor active layer of the memory TFT is 10 to 40 nm.

It is preferable that the semiconductor active layer of the memory TFT has such a thickness that is more likely to cause impact ionization than the semiconductor active layer of the switching TFT.

It is preferable that a tunnel current flowing between the floating, gate electrode and the semiconductor active layer of the memory TFT is twice or more of a tunnel current flowing between the gate electrode and the semiconductor active layer of the switching TFT.

It is preferable that the memory TFT and the switching TFT are p-channel TFTs.

The present invention provides a nonvolatile memory including at least a driver circuit of memory cells in addition to the memory cell array, wherein the memory cell array and the driver circuit of the memory cell are integrally formed on the insulating substrate.

The present invention provides a semiconductor device at least including a pixel circuit in which a plurality of pixel TFTs are arranged in matrix on an insulating substrate, a driver circuit constituted by TFTs for driving the plurality of pixel TFTs, and the nonvolatile memory,

wherein the pixel circuit, the driver circuit and the nonvolatile memory are integrally formed on the insulating substrate.

A liquid crystal display device, an EL (electroluminescence) display device or the like is provided as the semiconductor device. The EL display device is also called a light emitting device or a light emitting diode. The EL devices referred to this specification include triplet-based light emission devices and/or singlet-based light emission devices, for example.

A display, a video camera, a head-mounted type display, a DVD display, a goggle type display, a personal computer, a portable telephone, a car audio or the like is provided as the semiconductor device.

The present invention provides a method of manufacturing a nonvolatile memory including at least a memory cell array in which memory cells are arranged in matrix, each memory cell consisting of a memory TFT and a switching TFT, the method including the steps of:

forming a first amorphous semiconductor layer and a second amorphous semiconductor layer on an insulating substrate;

crystallizing the first amorphous semiconductor layer and the second amorphous semiconductor layer to form a crystalline semiconductor layer including a region having a first thickness and a region having a second thickness; and

forming the memory TFT including the region having the first thickness as a semiconductor active layer and the switching TFT including the region having the second thickness as a semiconductor active layer in the crystalline semiconductor layer,

wherein the first thickness is thinner than the second thickness.

In the method of manufacturing a nonvolatile memory, it is preferable that thicknesses of the semiconductor active layers of the memory TFT and the switching TFT are 1 to 150 nm.

The present invention provides a method of manufacturing a nonvolatile memory including at least a memory cell array in which memory cells are arranged in matrix, each memory cell consisting of a memory TFT and a switching TFT, the method including the steps of:

forming a first amorphous semiconductor layer and a second amorphous semiconductor layer on an insulating substrate;

crystallizing the first amorphous semiconductor layer and the second amorphous semiconductor layer to form a crystalline semiconductor layer including a region having a first thickness and a region having a second thickness;

forming the memory TFT including the region having the first thickness as a semiconductor active layer in the crystalline semiconductor layer; and

forming the switching TFT including the region having the second thickness as a semiconductor active layer,

wherein the first thickness is 1 to 100 nm, and the second thickness is 1 to 150 nm.

In the method of manufacturing a nonvolatile memory, it is preferable that the thickness of the semiconductor active layer of the memory TFT is 1 to 50 nm and that the thickness of the semiconductor active layer of the switching TFT is 10 to 100 nm.

In the method of manufacturing a nonvolatile memory, it is preferable that the thickness of the semiconductor active layer of the memory TFT is 10 to 40 nm.

In the method of manufacturing a nonvolatile memory, it is preferable that the semiconductor active layer of the memory TFT has a such thickness that is more likely to cause impact ionization than the semiconductor active layer of the switching TFT.

In the method of manufacturing a nonvolatile memory, it is preferable that a tunnel current flowing between the floating gate electrode and the semiconductor active layer of the memory TFT is twice or more of a tunnel current flowing between the gate electrode and the semiconductor active layer of the switching TFT.

In the method of manufacturing a nonvolatile memory, it is preferable that the memory TFT and the switching TFT are p-channel TFTs.

The present invention provides a method of manufacturing a nonvolatile memory including at least a driver circuit of a memory cell in addition to the memory cell array, wherein the memory cell array and the driver circuit of the memory cell are integrally formed on the insulating substrate.

The present invention provides a method of manufacturing a semiconductor device using the method of manufacturing a nonvolatile memory, wherein: the semiconductor device includes at least a pixel portion, a driver circuit for driving the pixel portion, and a nonvolatile memory manufactured by the method of manufacturing a nonvolatile memory; and

the pixel portion, the driver circuit and the nonvolatile memory are integrally formed on an insulating substrate.

A method of manufacturing a liquid crystal display device, an EL display device or the like is provided as the method of manufacturing a semiconductor device.

A method of manufacturing a display, a video camera, a head-mounted type display, a DVD display, a goggle type display, a personal computer, a portable telephone, a car audio, or the like is provided as the method of manufacturing a semiconductor device.

### BRIEF DESCRIPTION OF THE DRAWINGS

FIG. 1 is a diagram showing the circuit structure of a nonvolatile memory according to the present invention;

FIG. 2 is a cross-sectional view of a memory cell constituting a nonvolatile memory according to the present invention;

FIGS. 3A to 3D are diagrams showing the fabrication steps of a nonvolatile memory according to Embodiment 1;

FIGS. 4A to 4D are diagrams showing the fabrication steps of a nonvolatile memory according to Embodiment 1;

FIGS. 5A to 5D are diagrams showing the fabrication steps of a nonvolatile memory according to Embodiment 1;

FIGS. 6A to 6D are diagrams showing the fabrication steps of a nonvolatile memory according to Embodiment 1;

FIG. 7 is a top view of a memory cell constituting a nonvolatile memory according to the present invention;

FIG. 8 is a circuit diagram of a memory cell constituting a nonvolatile memory according to Embodiment 4;

FIGS. 9A to 9D are diagrams showing the fabrication steps of a nonvolatile memory according to Embodiment 2;

FIGS. 10A to 10D are diagrams showing the fabrication steps of a nonvolatile memory according to Embodiment 2;

FIGS. 11A and 11B are diagrams showing the fabrication steps of a nonvolatile memory according to Embodiment 2;

FIG. 12 is a diagram showing an electro-optical device using, a nonvolatile memory according to Embodiment 8;

FIG. 13 is a diagram showing an electro-optical device using a nonvolatile memory according to Embodiment 8;

FIGS. 14A to 14F are diagrams showing electrical devices using a nonvolatile memory according to Embodiment 9; and

FIGS. 15A and 15B are diagrams showing electrical devices using a nonvolatile memory according to Embodiment 9.

### DESCRIPTION OF THE PREFERRED EMBODIMENTS

### [Embodiment Mode]

Hereinafter, a circuit diagram of a nonvolatile memory and a driving, method thereof according to the present invention will be described for the case of m×n hits. The top structure and the cross-sectional structure of the memory cell constituting the nonvolatile -memory will be described, taking some examples.

In addition, a method of manufacturing a nonvolatile memory according to the present invention will be briefly described. The manufacturing method will be described in detail in Embodiments 1 and 2.

A nonvolatile memory in this embodiment is formed integrally with its driver circuit (in this embodiment mode, an address decoder) and other peripheral circuits, and with other components of the semiconductor device depending on the case, on an insulating substrate. In this embodiment mode, an EEPROM (Electrically Erasable and Programmable Read Only Memory) is particularly described as a nonvolatile memory.

FIG. 1 shows a circuit diagram of an m×n-bit nonvolatile memory according to the present invention. In this embodiment mode, the m×n-bit nonvolatile memory includes a plurality of electrically erasable memory TFTs (memory elements) Tr1, a plurality of switching TFTs Tr2, an X-address decoder 101, a Y-address decoder 102, and other peripheral circuits 103 and 104. The other peripheral circuits include an address buffer circuit, a control logic circuit and the like. These circuits are provided depending, on the need. Each of the memory TFTs Tr1 is a TFT having a floating gate where 1-bit data is recorded. In the present invention, the memory TFT Tr1 and the switching TFT Tr2 are required to be TFTs having the same conductivity. The memory TFT Tr1 and the switching TFT Tr2 may be either n-channel TFTs or p-channel TFTs; preferably, these TFTs are p-channel TFTs.

A source electrode of the memory TFT Tr1 is electrically connected to a drain electrode of the switching TFT Tr2. A series connection circuit of these two TFTs constitutes a 1-bit memory cell. In this embodiment, such memory cells are arranged in matrix of m memory cells in row and n memory cells in column (m and n are integers of 1 or more, respectively). Since each memory cell can store information of 1 bit, a nonvolatile memory of this embodiment has an m×n bit memory capacity.

As shown in FIG. 1, the memory cells constituting the m×n-bit nonvolatile memory are respectively denoted by the reference symbols (1, 1), (2,1) . . . through (n, m). The memory cells arranged in each row are connected to signal lines denoted by the reference symbols A1, B1 . . . through An, Bn at their both ends while the memory cells arranged in each column are connected to signal lines C1, D1 . . . through Cm, Dm. Specifically, a signal line Ai is connected to a drain electrode of the memory TFT Tr1 included in each of the memory cells (i,1), (i,2) through (i,m) arranged in the i-th column, while a signal line Bi is connected to a source electrode of the switching TFT Tr2 included in each of the memory cells arranged in the i-th column (i is an integer equal to or larger than 1 and equal to or smaller than n). A signal line Cj is connected to a control gate electrode of the memory TFT Tr1 included in the memory cells (1, j), (2, j) through (n, j) arranged in the j-th row, while a signal line Dj is connected to a gate electrode of the switching TFT Tr2 in the memory cells arranged in the j-th row (j is an integer equal to or larger than 1 and equal to or smaller than n).

The signal lines A1, B1 through An, Bn are connected to the X-address decoder 101, while the signal lines C1, D1 through Cm, Dm are connected to the Y-address decoder 102. The X-address decoder 101 and the Y-address decoder 102 specify a specific memory cell to write, read out and erase data for this cell.

The operation of a nonvolatile memory of this embodiment mode will be described, taking the memory cell (1, 1) in FIG. 1 as an example.

First, in the case where data is to be written on the memory TFT Tr1, the switching TFT Tr2 is turned ON via the single line D1. An appropriate potential difference is applied between the drain electrode of the memory TFT Tr1 and the source electrode of the switching TFT Tr2 via the signal lines A1 and B1. Then, a high positive voltage (for example, 20 V) is applied to the control gate of the memory TFT Tr1 to accelerate carriers (in this case, holes) moving in a channel formation region of the memory TFT Tr1. As a result, weak avalanche breakdown or impact ionization occurs to generate a large number of high-energy electrons (hot electrons). The hot electrons overpass the energy barrier of a gate insulating film to be injected into a floating gate electrode. In this manner, electric charges are accumulated in the floating gate electrode to perform writing. A threshold voltage of the memory TFT Tr1 varies depending on the amount of electric charges accumulated in the floating gate electrode.

In the case where data is to be read out from the memory cell, for example, the switching TFT Tr2 is turned ON via the signal line D1, then a voltage of 0 V is applied to the control gate of the memory TFT Tr1 via the signal line C1 to drop the voltage of the switching TFT Tr2 to GND via the signal line B1. As a result, it is determined whether the memory TFT Tr1 becomes conductive or non-conductive depending on the amount of electric charges accumulated in the floating gate electrode of the memory TFT Tr1, thereby reading out the data stored in the memory cell through the signal line A1.

Next, in the case where data stored in the memory TFT Tr1 is to be erased, the switching TFT Tr2 is turned ON via the signal line D1, and the voltage of source electrode of the switching TFT Tr1 is dropped to GND via the signal line B1. A high negative voltage (for example, −20 V) is applied to the signal line C1 to discharge the electrons trapped in the floating gate electrode toward the drain region due to a tunnel current. As a result, the stored date is erased.

Table 1 shows specific examples of voltages applied to the signal lines A1, B1, C1 and D1 based on the above-described operation. It is assumed that the memory TFT Tr1 and the switching TFT Tr2 are both p-channel TFTs.

TABLE 1

| | A1 (V) | B1 (V) | C1 (V) | D1 (V) |
|---|---|---|---|---|
| writing | −10 | GND | 20 | −5 |
| On reading | 0/−5 | GND | 0 | −5 |
| On easing | (floating) | GND | −20 | −5 |

The voltages shown in Table 1 applied to the signal lines are merely examples; the values of the voltages are not limited thereto. For example, the voltage applied to the memory TFT depends on the thickness of the semiconductor active layer of the memory TFT, the amount of a capacitor between the control gate electrode and the floating gate electrode, and the like. An operation voltage of the memory TFT correspondingly changes with the voltage applied to the memory TFT.

The memory TFT Tr1 and the switching TFT Tr2 may be n-channel TFTs. In such a case, all voltages to be applied to the signal line D1 may, be set to 5 V. In the case where the n-channel TFT is used as the memory TFT, a larger current flows during writing than in the case where the p-channel TFT is used. As a result, the n-channel TFT may be deteriorated in a shorter period of time. Therefore, it is preferable that the memory TFT Tr1 is a p-channel TFT in this embodiment mode.

In the case where writing/erasing of the memory TFT is performed in this embodiment mode, a voltage of +20/−20 V is not applied at once to the control gate electrode of the memory TFT; a voltage lower than these voltages may be applied with a plurality of pulses. In this case, the TFT can be prevented from being deteriorated to certain degree.

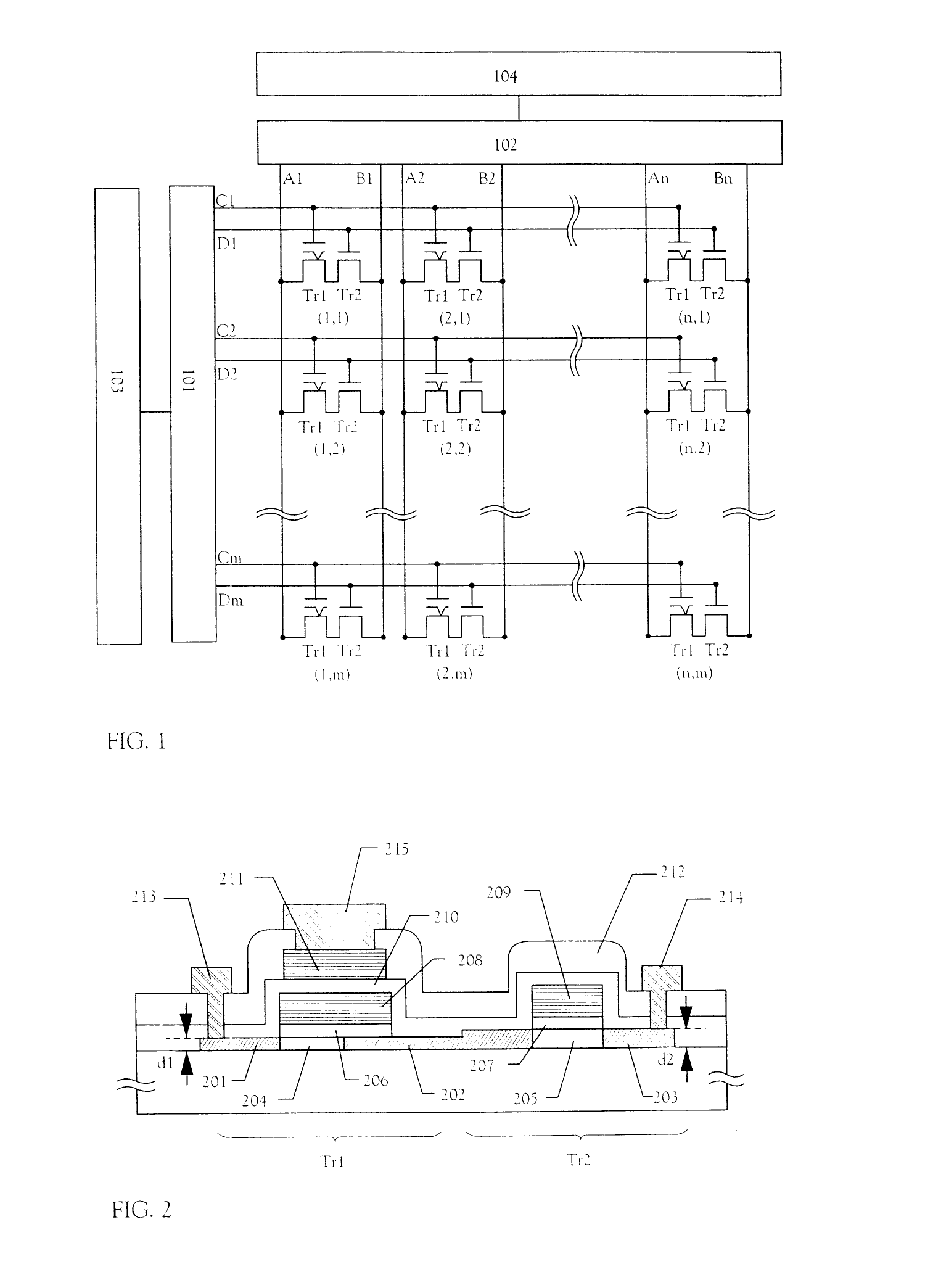

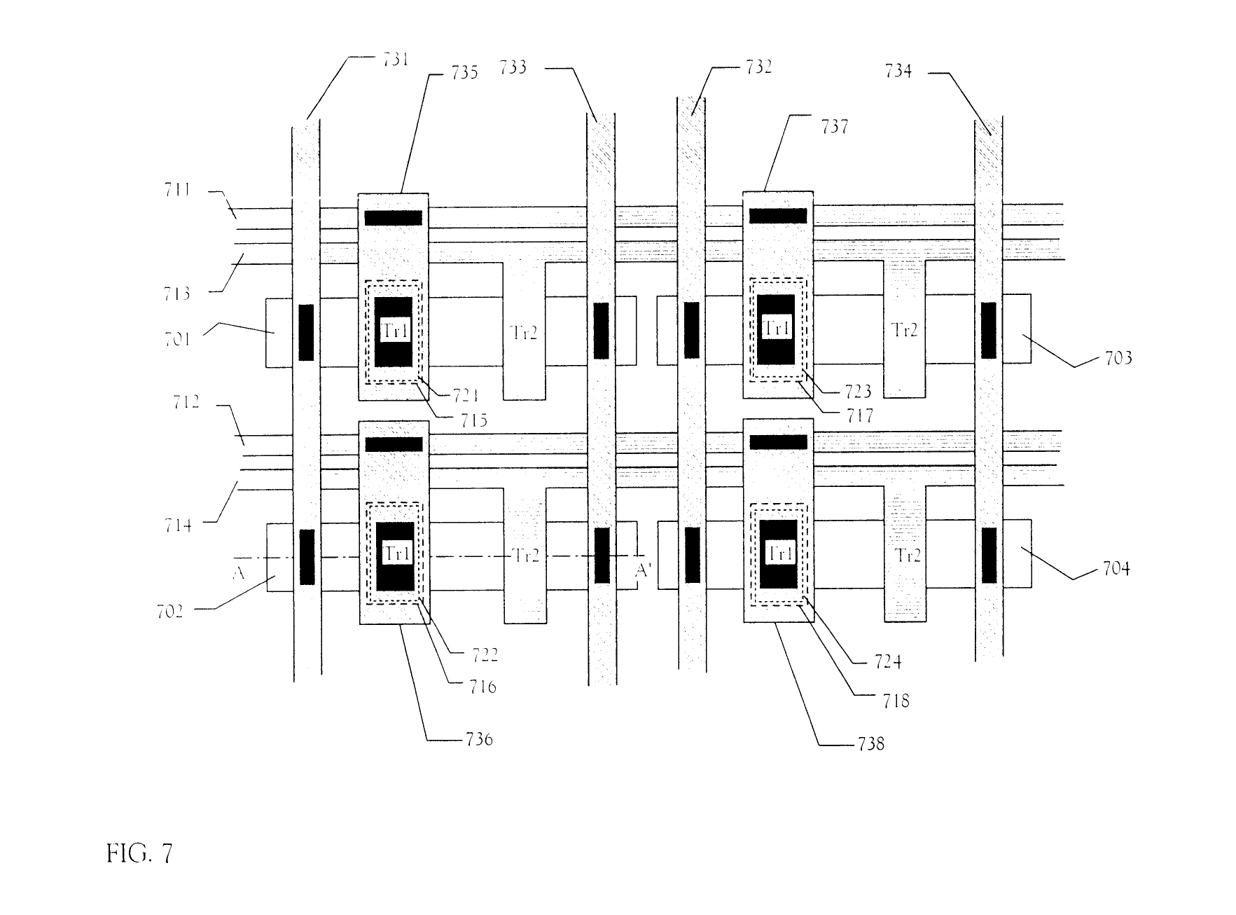

Next, the top structure and the cross-sectional structure of the memory cells constituting a nonvolatile memory according to the present invention will he described with reference to FIGS. 7 and 2.

First, an example of the top view of the memory cells constituting the nonvolatile memory according to the present invention is shown. FIG. 7 shows the top view of a region including four memory cells (1, 1), (1, 2), (2, 1) and (2, 2) (see FIG. 1).

In FIG. 7, regions 701 through 704 are semiconductor active layers. Each pair of the memory TFT Tr1 and the switching TFT Tr2 is formed on the same semiconductor active layer. Among first wiring layers 711 through 714, the wirings 713 and 714 are used as gate electrodes of the switching TFTs Tr2 and the signal lines C1 and C2. The wirings 711 and 712 are used as the signal lines D1 and D2. Floating gate electrodes 715 through 718 of the memory TFTs Tr1 are formed simultaneously with the first wiring layers 711 through 714. Among second wiring layers 731 through 738, the wirings 731 and 732 are used as the signal lines A1 and A2 connected to the source regions of the memory TFTs Tr1, while the wirings 733 and 734 are used as the signal lines B1 and B2 connected to the drain regions of the switching TFTs Tr2. The wirings 735 through 738 are used as wirings for connecting the control gate electrodes 721 through 724 of the memory TFTs Tr1 with the signal lines D1 and D2. In FIG. 7, the black regions indicate that contacts with the underlying wiring or semiconductor layer are formed. Moreover, the wirings illustrated with the same hatching are the same wiring layers.

Next, a cross-sectional view of the memory cell constituting a nonvolatile memory according to the present invention is shown. FIG. 2 shows a cross-sectional structure of the memory cell shown in FIG. 7 (for example, a cross-sectional structure of the n-memory cell (1, 2) taken along the line A-A in FIG. 7).

In FIG. 2, the left TFT is the memory TFT Tr1 while the right TFT is the switching TFT Tr2. The semiconductor active layer forming the memory TFT Tr1 and the switching TFT Tr2 includes source/drain regions 201, 202 and 203 and channel formation regions 204 and 205. Insulating films 206, 210 and 207 are a first gate insulating film and a second gate insulating film of the memory TFT and a gate insulating film of the switching TFT, respectively. Electrodes 208, 211 and 209 are a floating gate electrode and a control gate electrode of the memory TFT and a gate electrode of the switching TFT, respectively. An insulating film 212 is an interlayer insulating film. Wirings 213, 214 and 215 are a drain wiring of the memory TFT Tr1, a source wiring of the switching TFT Tr2, and a control gate wiring of the memory TFT Tr1, respectively.

As shown in FIG. 2 (and FIG. 7), in the present invention, the semiconductor active layer of the memory TFT Tr1 is directly continuous with the semiconductor active layer of the switching TFT Tr2. In other words, the source region of the memory TFT Tr1 and the drain region of the switching TFT Tr2 are electrically connected with each other by sharing the semiconductor active layer. With such a structure, the area of the memory cell can be considerably reduced as compared with the case where the memory TFT Tr1 and the switching TFT Tr2 are formed on different semiconductor active layers. As a result, the size of the nonvolatile memory and the size of the semiconductor device including the nonvolatile memory can be reduced.

Moreover, as shown in FIG. 2, the semiconductor active layer (thickness: d1) of the memory TFT Tr1 is formed thinner than the semiconductor active layer (thickness: d2) of the switching TFT Tr2; that is, the relationship d1<d2 is established. With such a structure, impact ionization is more likely to occur in the semiconductor active layer of the memory TFT Tr1. As a result, injection of electric charges to the floating (late electrode of the memory TFT Tr1 is likely to occur. The thickness of the semiconductor active layer of the TFTs constituting the Y-address decoder 101, the Y-address decoder 102, and other peripheral circuits may be set to be equal to the thickness d2 of the semiconductor active layer of the switching TFT Tr2.

The source region 202 of the memory TFT Tr1 partially overlaps the floating gate region 208 through the gate insulating film 206 to reserve a tunnel current on erasing It is preferred that the tunnel current flowing into the semiconductor active layer of the memory TFT Tr1 is twice or more of a tunnel current flowing into the semiconductor active layer of the switching TFT Tr2.

For the example of the cross-sectional structure of the memory cell, Embodiment 2 can be referred to in addition to this embodiment mode. As described above, the semiconductor active layer of the memory TFT Tr1 is formed thinner than the semiconductor active layers of the TFTs constituting the address decoders and other peripheral circuits and the switching TFT in the present invention; or the semiconductor active layer of the memory TFT Tr1 is formed to have a thickness of 1 to 100 nm (preferably, 1 to 50 nm, more preferably 10 to 40 nm).

The number of rewritable times and the information holding time are important factors for the nonvolatile memory. In order to increase the number of rewritable times, it is required to reduce a voltage to be applied to the control gate electrode of the memory TFT. Since the semiconductor active layer of the memory TFT is formed thin as described above in the nonvolatile memory according to the present invention, impact ionization is likely to occur to allow writing and erasing to the memory TFT at a low voltage. This is an innovative solution for the problems that the gate insulating film is deteriorated due to a relatively thin gate insulating film or that carriers accumulated in the floating gate electrodes flow out due to an increased temperature in a nonvolatile memory conventionally made of bulk silicon.

Next, a method of manufacturing a nonvolatile memory according to the present invention will be briefly described. For a detailed manufacturing method, Embodiments 1 and 2 can be referred to.

First, a first amorphous semiconductor layer is formed on an insulating substrate. After patterning of the first amorphous semiconductor layer, a second amorphous semiconductor layer is formed. The first and second amorphous semiconductor layers are crystallized to form a crystalline semiconductor layer including a region having a first thickness and a region having a second thickness. In the case where a driver circuit of the memory cells and other peripheral circuits are integrally formed on the insulating substrate, a crystalline semiconductor layer having the second thickness is formed in such a region.

The crystalline semiconductor film in this specification generically indicates semiconductor films containing an amorphous structure, and includes amorphous semiconductor films and microcrystalline semiconductor films. Alternatively, a compound semiconductor film containing an amorphous structure such as an amorphous silicon germanium film may be used.

The crystalline semiconductor layer in this specification generically indicates semiconductor layers containing a crystal structure, and includes single-crystalline semiconductor films and polycrystalline semiconductor films. As a polycrystalline semiconductor film having particularly excellent crystallinity, a semiconductor film having a crystal structure in which a group of rod-shaped crystals are arranged (see Embodiment 1), manufactured by the technique described in Japanese Patent Application Laid-Open No. Hei 10-247735, is included.

Thereafter, the memory TFT including the region having the first thickness as a semiconductor active layer and the switching TFT including the region having the second thickness as a semiconductor active layer are formed to allow the manufacture of a nonvolatile memory including a memory cell in which the semiconductor active layer of the memory TFT is continuous with that of the switching TFT. Moreover, by simultaneously forming a CMOS circuit including a crystalline semiconductor layer having the second thickness as a semiconductor active layer, a driver circuit of the memory cells and other peripheral circuits can be integrally formed.

It is apparent that the first and second thicknesses can be freely set within the range allowed by the device. The first thickness is formed thinner than the second thickness, or the first thickness is formed to be 1 to 100 nm (preferably, 1 to 50 nm, more preferably, 10 to 40 nm), thereby allowing the manufacture of the nonvolatile memory according to the present invention.

The method of manufacturing a nonvolatile memory described above allows the nonvolatile memory of the present invention to be integrally formed with any components of the semiconductor device that can be manufactured by a thin film technique.

The use of the manufacturing method described in Embodiment I allows the manufacture of TFTs having enhanced properties. As a result, the TFTs exhibiting enhanced properties in mobility, a threshold voltage and the like are integrally formed with the required peripheral circuits and components of the semiconductor device, thereby allowing the realization of various nonvolatile memories and semiconductor devices including a nonvolatile memory.

### [Embodiment 1]

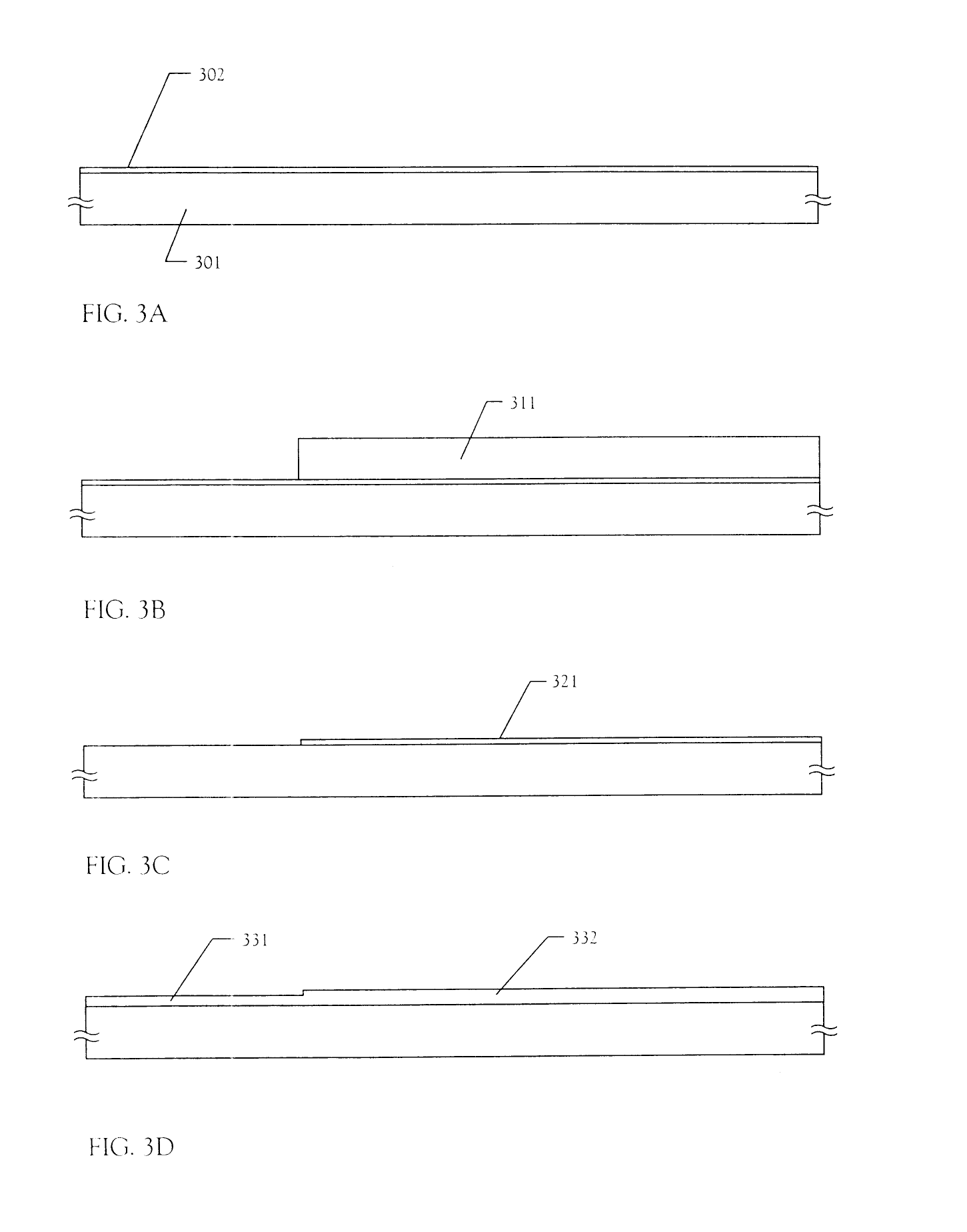

In Embodiment 1, a method of manufacturing a nonvolatile memory using the present invention will be described with reference to FIGS. 3A to 6D. In FIGS. 3A to 6D, a memory TFT (a p-channel TFT) and a switching TFT (a p-channel TFT) constituting a memory cell, and two TFTs (a p-channel TFT and an n-channel TFT) constituting a CMOS circuit that is representative as a circuit constituting an address decoder or other peripheral circuits are described as examples.

According to the manufacturing method of a nonvolatile memory described below, it is understood that the nonvolatile memory of the present invention can be integrally formed with any components of the semiconductor device that can be manufactured by using a thin film technique.

In order to realize a nonvolatile memory and a semiconductor device, which have memory cells, an address decoder and other circuits constituted by TFTs on the same insulating substrate, TFTs having enhanced properties in mobility, a threshold voltage and the like are required. Particularly, a TFT including a semiconductor active layer made of amorphous silicon that is frequently used in a conventional nonvolatile memory is not sufficient. According to the manufacturing method described below, TFTs having enhanced properties can be fabricated, allowing the realization of a nonvolatile memory and a semiconductor device of the present invention.

FIGS. 3A through 3D are referred to. First, a quartz substrate 301 is prepared as a substrate having an insulating surface. Instead of the quartz substrate 301, a silicon substrate on which a thermal oxide film is formed may be used. Alternatively, an insulating film may be obtained by first forming an amorphous silicon film on a quartz substrate and then completely thermally oxidizing the amorphous silicon film. Furthermore, a quartz substrate or a ceramic substrate on which a silicon nitride film is formed as an insulating film may also be used.

Next, an amorphous silicon film 302 having a thickness of 25 nm is formed by a known film formation method (FIG. 3A). The film 302 is not necessarily limited to an amorphous silicon film; any amorphous semiconductor films (including microcrystalline semiconductor films and compound semiconductor films containing an amorphous structure such as an amorphous silicon germanium film) may be used.

Next, a resist film is formed, and then the patterning is performed to form a mask 311 (FIG. 3B). Thereafter, the amorphous silicon film 302 is etched to form an amorphous silicon film 321 that is partially formed on the substrate (FIG. 3C). As etching for the amorphous silicon film 321, any of dry etching and wet etching may be employed. For example, an etchant of CF₄+O₂ may be used in the case of dry etching, while an etchant of fluoric acid+nitric acid or the like may be used in the case of wet etching.

Next, another amorphous silicon film is formed to a thickness of 50 nm by the above-mentioned method to form amorphous silicon films 331 and 332 as shown in FIG. 3D. In this embodiment, the thicknesses of the amorphous silicon films 331 and 332 arc controlled so that the thickness of the amorphous film 331 is 50 nm and the thickness of the amorphous silicon film 332 is 75 nm. The films 331 and 332 are not limited to amorphous silicon films, and may be any amorphous semiconductor films (including microcrystalline semiconductor films and compound semiconductor films containing an amorphous structure such as an amorphous silicon germanium film).

It is desirable that the surfaces of the amorphous silicon film 321 and the quartz substrate 301 are purified before the second formation of the amorphous silicon film.

For the formation of the amorphous silicon films 331 and 332, another method may be used. As an alternative method, for example, an amorphous silicon film is entirely formed to a thickness of 75 nm by the above-mentioned method and a mask is partially formed thereon so as to perform the etching described above, thereby obtaining an amorphous silicon film having a partially decreased thickness.

The amorphous silicon film 331 serves as a semiconductor active layer of the memory TFT in the later process whereas the amorphous silicon film 332 serves as a semiconductor active layer of the switching TFT, a CMOS circuit in the periphery, and the like in the later process.

In the case where the final thickness of the semiconductor active layer is 150 nm or more, particularly, 200 nm or more, the occurrence of impact ionization peculiar to SOI is rare. Accordingly, the frequency of occurrence of impact ionization is as low as that in a nonvolatile memory using bulk silicon. As a result, the characteristics of the nonvolatile memory manufactured by the SOI technique cannot be obtained. Therefore, it is preferable that the final thicknesses of the semiconductor active layers are 1 to 150 nm in the present invention.

Although the final thickness of the amorphous silicon film 331 of the memory TFT is set to 50 nm and the final thickness of the amorphous silicon film 332 of the switching TFT, a CMOS circuit in the periphery and the like is set to 75 nm as described above in this embodiment, the thicknesses of these films are not limited thereto. It is sufficient to form the amorphous silicon film 331 to have a thickness of 1 to 100 nm (preferably, 1 to 50 nm, more preferably, 10 to 40 nm) and the amorphous silicon film 332 to have a thickness of 1 to 150 nm (preferably, 10 to 100 nm).

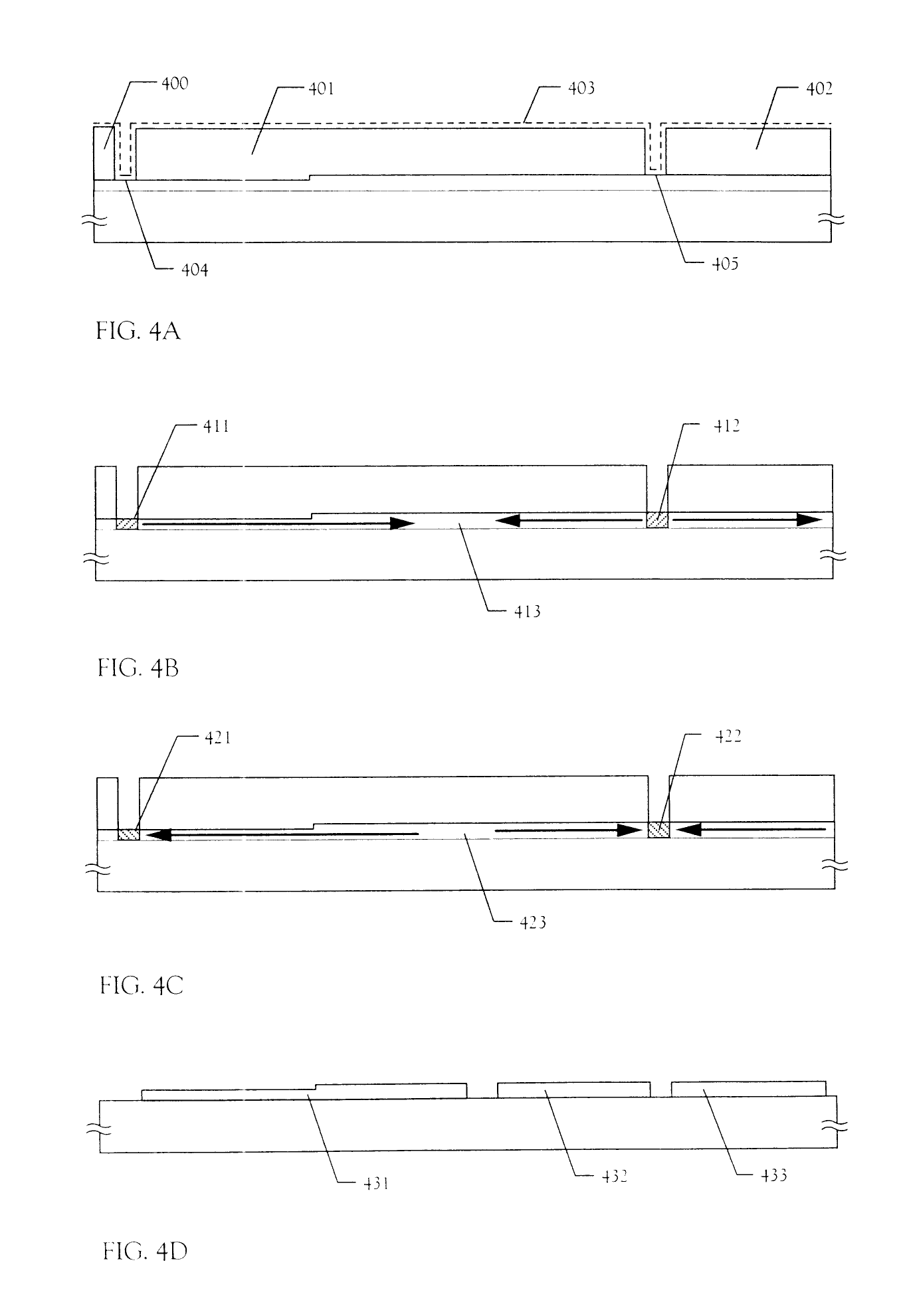

Next, the step of crystallizing the amorphous silicon films 331 and 332 is conducted. For the steps from there on up to FIG. 4B, Japanese Patent Application Laid-Open No. Hei 10-247735 by the applicant of the present invention can be cited in its totality. This Patent Application discloses a technique related to a crystallization method of a semiconductor film using an element such as Ni as a catalyst.

First, protective films 400 to 402 having apertures 404 and 405 therethrough are formed. In this embodiment, a silicon oxide film having a thickness of 150 nm is used as the protective films 400 to 402. A layer 403 containing nickel (Ni) (a Ni-containing layer) is formed on the protective films 400 to 402 by spin coating. For the formation of this Ni-containing layer, the above-mentioned Patent Application may be referred to (FIG. 4A).

In addition to nickel, cobalt (Co), iron (Fe), palladium (Pd), platinum (Pt), copper (Cu), gold (Au), germanium (Ge), lead (Pb), indium (In) or the like can be used as a catalyst element.

The above catalyst element can be added not only by spin coating, but also by ion implantation utilizing a resist mask, plasma doping, or sputtering. Since the use of such techniques facilitates the reduction of the area occupied by the region where the catalyst element is added and the control of a crystal growth length, these techniques are effective for constituting a refined circuit.

Next, as shown in FIG. 4B, a heat treatment is conducted at 570° C. for 14 hours in an inert atmosphere to crystallize the amorphous silicon films 331 and 332. On this crystallization, the crystallization proceeds substantially parallel to the substrate from regions 411 and 412 that are in contact with Ni (hereinafter, referred to as Ni-added regions) to form a crystalline silicon film 413 containing a crystal structure in which rod-shaped crystals are gathered to be arranged. The crystalline silicon film 413 is advantageous for its entirely excellent crystallinity because relatively similar sized crystals are aggregated. It is preferable to employ the heating treatment temperature of 500 to 700° C. (typically, 550 to 650° C.) and the treatment time of 4 to 24 hours.

Next, as shown in FIG. 4C, an element selected from the members of Group 15 in the periodic table (preferably, phosphorus) is added to the Ni-added regions 411 and 412 using the protective films 400 to 402 as masks. In this manner, regions 421 and 422 where phosphorus is added at a high concentration (hereinafter, referred to as phosphorus-added regions) are formed.

Then, as shown in FIG. 4C, a heat treatment is conducted at 600° C. for 12 hours in an inert atmosphere. This thermal treatment moves Ni present in the crystalline silicon film 423, so that almost all Ni is finally trapped in the phosphorus-added regions 421 and 422 as indicated with arrows. This phenomenon is considered to be caused by a gettering effect of phosphorus for a metal element (Ni in this embodiment).

As a result of this step, the concentration of Ni remaining in the crystalline silicon film 423 is reduced to at least 2×10¹⁷ atoms/cm³ in terms of the measurement value by a SIMS (Secondary Ion Mass Spectrometer). Although Ni is a life time killer for the semiconductor, Ni at the above decreased concentration does not have any adverse effects on the TFT properties. Since the concentration mentioned above is almost the limit that can be measured by a current SIMS analysis, the actual concentration is considered to be lower (2×10¹⁷ atoms/cm³ or less) than this value.

In this manner, the crystalline silicon film 423 crystallized by using the catalyst, in which the catalyst is reduced to the level that does not have any adverse effects on the operation of TFTs, is obtained. Thereafter, the protective films 400 to 402 are removed to form island-like semiconductor layers (active layers) 431 to 433 using only the crystalline silicon film 423 that does not include the phosphorus-added regions 421 and 422, by a patterning step. In this step, the island-like semiconductor active layer 431 is formed to include two active regions having different thicknesses obtained by crystallizing the amorphous silicon films 331 and 332 (FIG. 4D). In the island-like semiconductor active layer 431, the thinner active region obtained by crystallizing the amorphous silicon film 331 serves as a semiconductor active layer of the memory TFT while the thicker active region obtained by crystallizing the amorphous silicon film 332 serves as a semiconductor layer of the switching TFT.

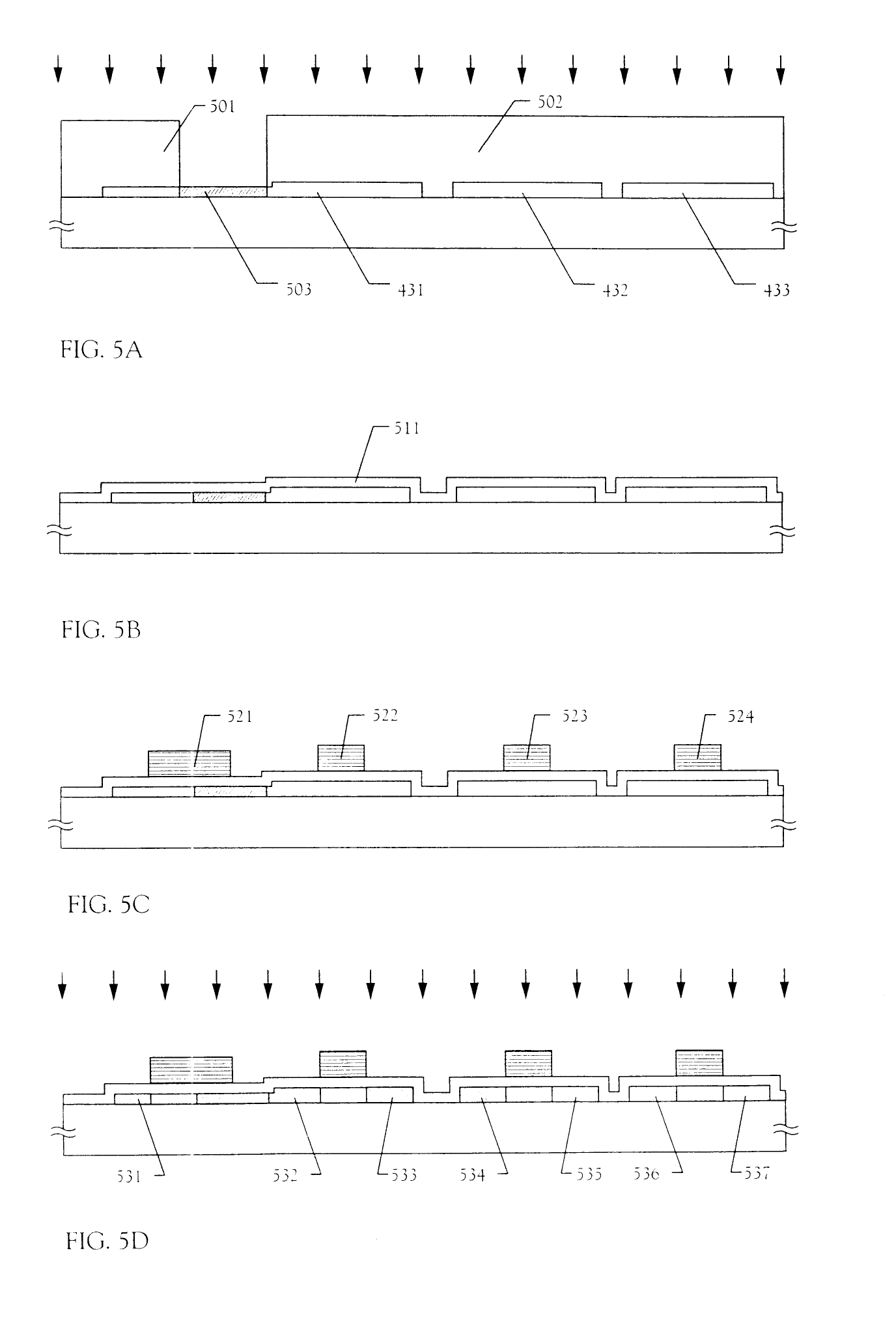

Next, the island-like semiconductor active layer 431 other than a region 503 which serves as a source region of the memory TFT in the later step is covered with a resist mask. Then, an impurity element for imparting a p-type conductivity (also referred to as a p-type impurity element) is added to the region 503 (FIG. 5A). In this embodiment, boron (B) is used as an impurity element, and an acceleration voltage for the addition of the impurity is set to about 10 keV. The dose is controlled so that the p-type impurity 503 formed by this step contains the p-type impurity element at the concentration of 1×10²⁰ to 1×10²¹ atoms/cm³ (typically, 2×10²⁰ to 5×10²⁰ atoms/cm³). In addition to boron (B), gallium (Ga), indium (In) and the like may be used as the p-type impurity element. It is sufficient to form the p-type impurity region 503 in this step so as to have a region overlapping a part of a floating gate electrode of the memory TFT that is formed in the later process through the gate insulating film. Thus, the region covered with the resist mask is not limited to that described in this embodiment (FIG. 5A); it is sufficient to form this region to include at least regions in the island-like semiconductor active layer 431 which are to be channel formation regions of the memory TFT and the switching TFT in the later step and the island-like semiconductor active layers 432 and 433.

As a result, in the island-like semiconductor active layer 431, the region 503 to be a source region of the memory TFT in the later process is formed. Since the remaining region of the island-like semiconductor active layer 431 and the island-like semiconductor active layers 432 and 433 are covered with resist mask 501 and 502, an impurity element is not added thereto.

Thereafter, the resist masks 501 and 502 are removed to form a gate insulating film 511 made of an insulating film containing silicon (FIG. 5B). The thickness of the gate insulating film 511 may be controlled within the range of 10 to 250 nm, taking an increase in thickness due to the later thermal oxidation step into account. Alternatively, the thickness of the gate insulating film for the island-like semiconductor layer of the memory TFT may be 10 to 50 nm with the thicknesses of the other gate insulating films being 50 to 250 nm. As a film formation method, a known vapor phase method (plasma CVD, sputtering or the like) may be used. In this embodiment, a silicon nitride oxide film having a thickness of 50 nm is formed by plasma CVD.

Next, a heat treatment is conducted at 950° C. for one hour in an oxidation atmosphere so as to perform a thermal oxidation step. The oxidation atmosphere may be either an oxygen atmosphere or an oxygen atmosphere to which a halogen element is added. In this thermal oxidation step, oxidation proceeds at the interface between the active layer and the silicon nitride oxide film to increase the thickness of the gate insulating film 511 by the thickness of the thermal oxide film. When the thermal oxide film is formed in this way, the interface between the semiconductor and the insulating film having an extremely small interface level can be obtained. Moreover, such formation is effective for preventing poor formation of the thermal oxide film at the edges of the active layer (edge thinning).

Next, an electrically conductive film having a thickness of 200 to 400 nm is formed. This electrically conductive film is subjected to patterning to form gate electrodes 521 to 524 (FIG. 5C). Channel lengths of two TFTs constituting a CMOS circuit and the switching TFT are determined depending on the line widths of the gate electrodes 521 to 524. For the formation of the gate electrodes, the gate electrode 521 (serving as a floating gate electrode in the later step) of the memory TFT is formed so as to partially overlap the p-type impurity region 503 through the gate insulating film 511. The overlapping region serves to sufficiently reserve a tunnel current that flows when the memory TFT executes erase.

Note that, although the gate electrode may be formed of a conductive film of a single layer, it is preferable to make a laminate film such as a two-layer or three-layer film as the need arises. As the material of the gate electrode, any well-known conductive films may be used. Specifically, it is possible to use a film made of an element selected from the group consisting of tantalum (Ta), titanium (Ti), molybdenum (Mo), tungsten (W), chromium (Cr), and silicon (Si), a film of nitride of the above element (typically a tantalum nitride film, tungsten nitride film, or titanium nitride film), an alloy film of combination of the above elements (typically Mo—W alloy, Mo—Ta alloy), or a silicide film of the above element (typically a tungsten silicide film, titanium silicide film).

In this embodiment, a laminate film of a tungsten nitride (WN) film having a thickness of 50 nm and a tungsten (W) film having a thickness of 350 nm is used. These may be formed by a sputtering method. When an inert gas of Xenon (Xe), Neon (Ne) or the like is added as a sputtering gas, film peeling due to stress can he prevented.

Next, the step of adding an impurity element for imparting one conductivity is performed. Phosphorus (P) or arsenic (As) may be used as an n-type impurity, boron (B), gallium (Ga), indium (In) or the like may be used as a p-type impurity.

First, as shown in FIG. 5D, an n-type impurity element (in this embodiment, phosphorus) is added in a self-aligning manner using the gate electrodes 521 to 524 as masks to form low concentration impurity regions (n- regions). The concentration of phosphorus in these low concentration impurity regions is controlled to be 1×10¹⁷ to 1×10¹⁹ atoms/cm³. An acceleration voltage may be set to about 80 keV.

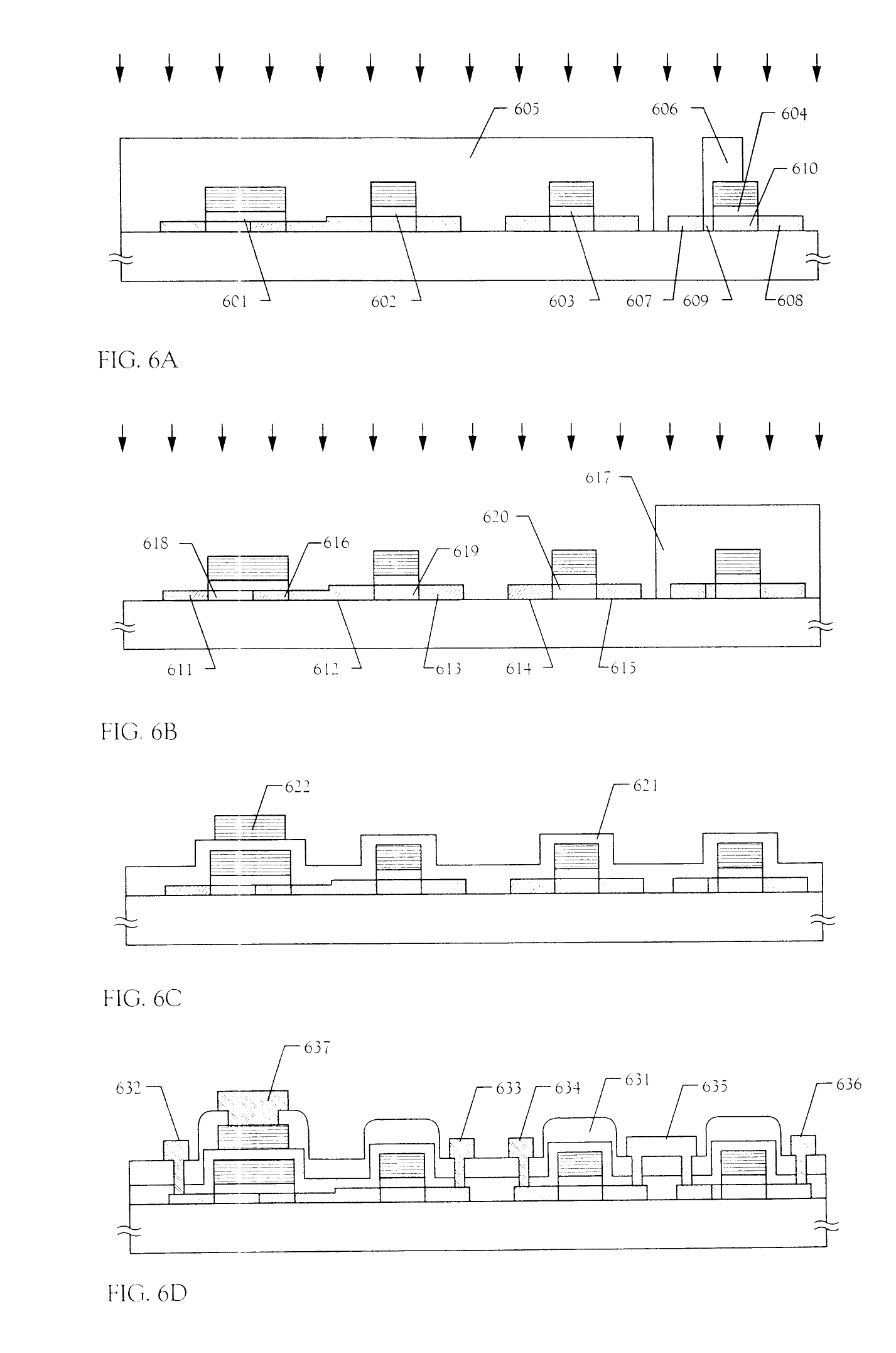

Next, the gate insulating film 511 is etched by dry etching using the gate electrodes 521 to 524 as masks so as to obtain regions 601 to 604 by patterning (FIG. 6A).

Next, as shown in FIG. 6A, resist masks 605 and 606 are formed to as to cover the entire p-channel TFT and a part of the n-channel TFT. Then, an n-type impurity element is added so as to form impurity regions 607 and 608 containing phosphorus at a high concentration. For the formation of these impurity regions, the concentration of the n-type impurity element is controlled to be 1×10²⁰ to 1×10²⁰ atoms/cm³ (typically, 2×10²⁰ to 5×10²⁰ atoms/cm³). In this embodiment, phosphorus is used as an impurity element, and an acceleration voltage on addition of the impurity is set to about 10 keV.

By conducting this step, the source/drain regions 607 and 608 of the n-channel TFT are formed. In the n-channel TFT in particular, a part of the low concentration impurity region (n region) 536 that is formed in the step shown in FIG. 5D remains. The remaining region serves as an LDD region of the n-channel TFT. As a result, the source/drain regions 607 and 608, the LDD region 609, and a channel formation region 610 of the n-channel TFT are formed.

Next, as shown in FIG. 6B, the resist masks 605 and 606 are removed, and a new resist mask 617 is formed. A p-type impurity element (boron is used in this embodiment) is then added, forming impurity regions 611 to 615 containing a high concentration of boron. Boron is added here at a concentration of 1×10²⁰ to 1×10²¹ atoms/cm³ (typically between 2×10²⁰ and 5×10²⁰ atoms/cm³) by ion doping using diborane (B₂H₆).

In this manner, the source/drain regions 611 to 616 (including the source region partially overlapping a floating gate electrode through the rate insulating film) and channel formation regions 618 and 620 are formed (FIG. 6B).

Next, as shown in FIG. 6C, after removal of a resist mask 617, an insulating film 621 containing silicon is formed (FIG. 6C). The insulating film 621 serves as a gate insulating film between the floating gate electrode and the control gate electrode in the memory TFT. The thickness of the insulating film 621 may be 10 to 250 nm. As a film formation method, a known vapor phase method (plasma CVD, sputtering or the like) may be employed. In this embodiment, a silicon nitride oxide film having a thickness of 50 nm is formed by plasma CVD.

Thereafter, the n-type or p-type impurity element that is added at each concentration is activated. As activation means, furnace annealing, laser annealing, lamp annealing and the like may be combined. In this embodiment, a heat treatment is conducted in an electrically heated oven at 550° C. for four hours in a nitrogen atmosphere. By this heat treatment, the damages of the active layer caused in the step of adding the impurity are repaired. The furnace annealing is preferred as activation means.

Next, an electrically conductive film having a thickness of 200 to 400 nm is formed. Then, the electrically conductive film is subjected to patterning, to form a ,ate electrode 622 (FIG. 6C). The control gate electrode 622 is formed so as to partially or entirely overlap the floating gate electrode through the insulating film 621.

Note that, although the control gate electrode may be formed of a conductive film of a single layer, it is preferable to make a laminate film such as a two-layer or three-layer film as the need arises. As the material of the gate electrode, any well-known conductive films may be used. Specifically, it is possible to use a film made of ant element selected from the group consisting of tantalum (Ta), titanium (Ti), molybdenum (Mo), tungsten (W), chromium (Cr), and silicon (SI), a film of nitride of the above element, an alloy film of combination of the above elements, or a silicide film of the above element.

In this embodiment, a laminate film of a tungsten nitride (WN) film having a thickness of 50 nm and a tungsten (W) film having, a thickness of 350 nm is formed by sputtering. When an inert gas of Xenon (Xe), Neon (Ne) or the like is added as a sputtering gas, film peeling, due to stress can be prevented.

Then, an interlayer insulating, film 631 is formed. An insulating film containing, silicon, an organic resin film or a laminate film formed of the combination thereof may be used as the interlayer insulating film 631. The thickness of the interlayer insulating, film 631 may be 400 nm to 1.5 mm. In this embodiment, a silicon nitride oxide film having a thickness of 500 nm is used as the interlayer insulating film 631.

Next, as shown in FIG. 6D, contact holes are formed through the interlayer insulating film 631 and the insulating film 621 to form source/drain wirings 632 to 636 and a control gate wiring 637. In this embodiment, a laminate film having a triple-layered structure, in which a Ti film having a thickness of 100 nm, an aluminum film containing Ti having a thickness of 300 nm and a Ti film having a thickness of 150 nm are successively formed by sputtering, is used as each wiring. It is apparent that any other electrically conductive film may be used instead.

Finally, a heat treatment is conducted at 300 to 450° C. for 1 to 12 hours in an atmosphere containing hydrogen at 3 to 100% so as to conduct a hydrogenation treatment. This step serves to terminate dangling bonds of the semiconductor film with thermally excited hydrogen. In this embodiment, a heat treatment is conducted at 350° C. for two hours in a hydrogen atmosphere so as to conduct a hydrogenation treatment. A another means of hydrogenation, plasma hydrogenation (using hydrogen excited by plasma) may be used instead. Moreover, the hydrogenation treatment may be performed before the formation of the contact holes.

By the above process, TFTs having a structure as shown in FIG. 6D can be manufactured.

### [Embodiment 2]

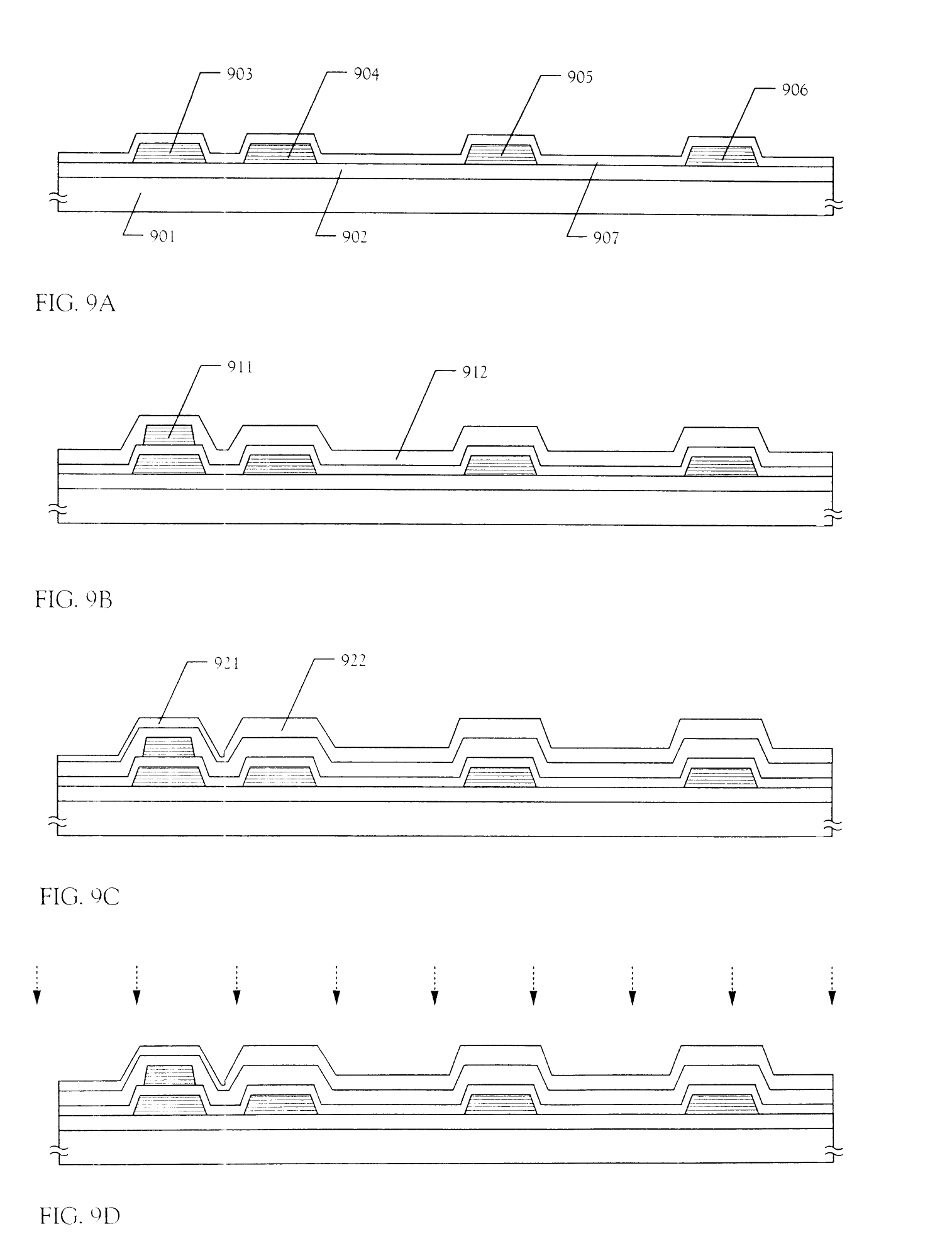

In this embodiment, the case where a nonvolatile memory is constituted with an inverted stagger TFT will be described with reference to FIGS. 9A through FIG. 11B. In FIGS. 9A through FIG. 11B, a memory TFT (a p-channel TFT) and a switching TFT (a p-channel TFT) constituting a memory cell, and two TFTs (a p-channel TFT and a n-channel TFT) constituting a CMOS circuit that is representative as a circuit constituting an address decoder or other peripheral circuits are taken as examples of TFTs constituting a nonvolatile memory according to the present invention.

Referring to FIG. 9A, a base film 902 made of a silicon oxide film is first formed on a glass substrate 901. Then, gate electrodes 903 through 906 are formed thereon. The gate electrode 903 serves as a control gate electrode of the memory TFT in the later step, while the gate electrode 904 serves as a gate electrode of the switching TFT in the later step. Although a chromium film having a thickness of 200 to 400 nm is used as the gate electrodes 903 to 906 in this embodiment, a film made of an aluminum alloy, tantalum, tungsten, molybdenum, silicon to which one conductivity is imparted, or the like may be used instead.

Next, a gate insulating film 907 having a thickness of 100 to 200 nm is formed on the gate electrodes 903 to 906. As the gate insulating film 907, a silicon oxide film, a silicon nitride film, a laminate film of a silicon oxide film and a silicon nitride film, or the like is used.

The gate insulating film on the memory TFT side defines the amount of a capacitor between a floating gate electrode to be formed in the next step and the control gate electrode. It is possible to control the voltage to be applied to the floating gate electrode by changing the thickness of the gate insulating film 907. Therefore, the thickness of the grate insulating film 907 is not limited to the above range. Moreover, the gate insulating film 907 may partially have a different thickness.

Next, a floating gate electrode 911 is formed (FIG. 9B). Although a chromium film is used as the floating gate electrode 911 in this embodiment, a film made of an aluminum alloy, tantalum, tungsten, molybdenum, silicon to which one conductivity is imparted, or the like may be used instead.

Next, an insulating film 912 is formed to a thickness of 10 to 50 nm. As the insulating film 912, a silicon oxide film, a silicon nitride film, a laminate film of a silicon oxide film and a silicon nitride film, or the like is used.

Next, amorphous silicon films 921 and 922 are formed in accordance with the method illustrated in FIGS. 3A to 3D (FIG. 9C). Although the final thickness of the amorphous silicon film 921 of the memory TFT is set to 50 nm and the final thickness of the amorphous silicon film 922 of the switching TFT is set to 75 nm, the thicknesses of the amorphous silicon film 921 and 922 are not limited thereto; it is sufficient to form the amorphous silicon film 921 to have a thickness of 1 to 100 nm (preferably, 1 to 50 nm, more preferably, 10 to 40 nm) and the amorphous silicon film 922 to have a thickness of 1 to 150 nm (preferably, 10 to 100 nm). The thickness of the amorphous silicon film of the TFTs constituting an address decoder or a peripheral circuit is set to be the same as that of the switching TFT.

The films 921 and 922 are not necessarily limited to amorphous silicon films; any amorphous semiconductor films (including microcrystalline semiconductor films and compound semiconductor films containing an amorphous structure such as an amorphous silicon germanium film) may be used as the films 921 and 922.

Next, the amorphous silicon films 921 and 922 are irradiated with laser light or strong light having similar intensity to that of laser light to crystallize the amorphous silicon films 921 and 922 (FIG. 9D). As laser light, excimer laser light is preferable. As an excimer laser, a pulse laser using KrF, ArF or XeCl as a light source may he employed.

As strong light having similar intensity to that of laser light, strong light emitted from a halogen lamp or a metal halide lamp, or strong light emitted from an infrared or ultraviolet lamp can be used.

In this embodiment, excimer laser light processed in a linear shape is scanned from one end to the other end of the substrate so as to crystalline the entire surfaces of the amorphous silicon films 921 and 922. For this crystallization, a sweep rate of laser light is 1.2 mm/s, a treatment temperature is a room temperature, a pulse frequency is 30 Hz, and laser energy is 300 to 315 mJ/cm². As a result of this crystallization step, crystalline silicon films are obtained.

As a method of crystallizing the amorphous semiconductor films in this embodiment, the crystallization method used in Embodiment 1 may be employed instead. In a similar manner, the crystallization method of this embodiment may be used as the crystallization method of the amorphous semiconductor films of Embodiment 1.

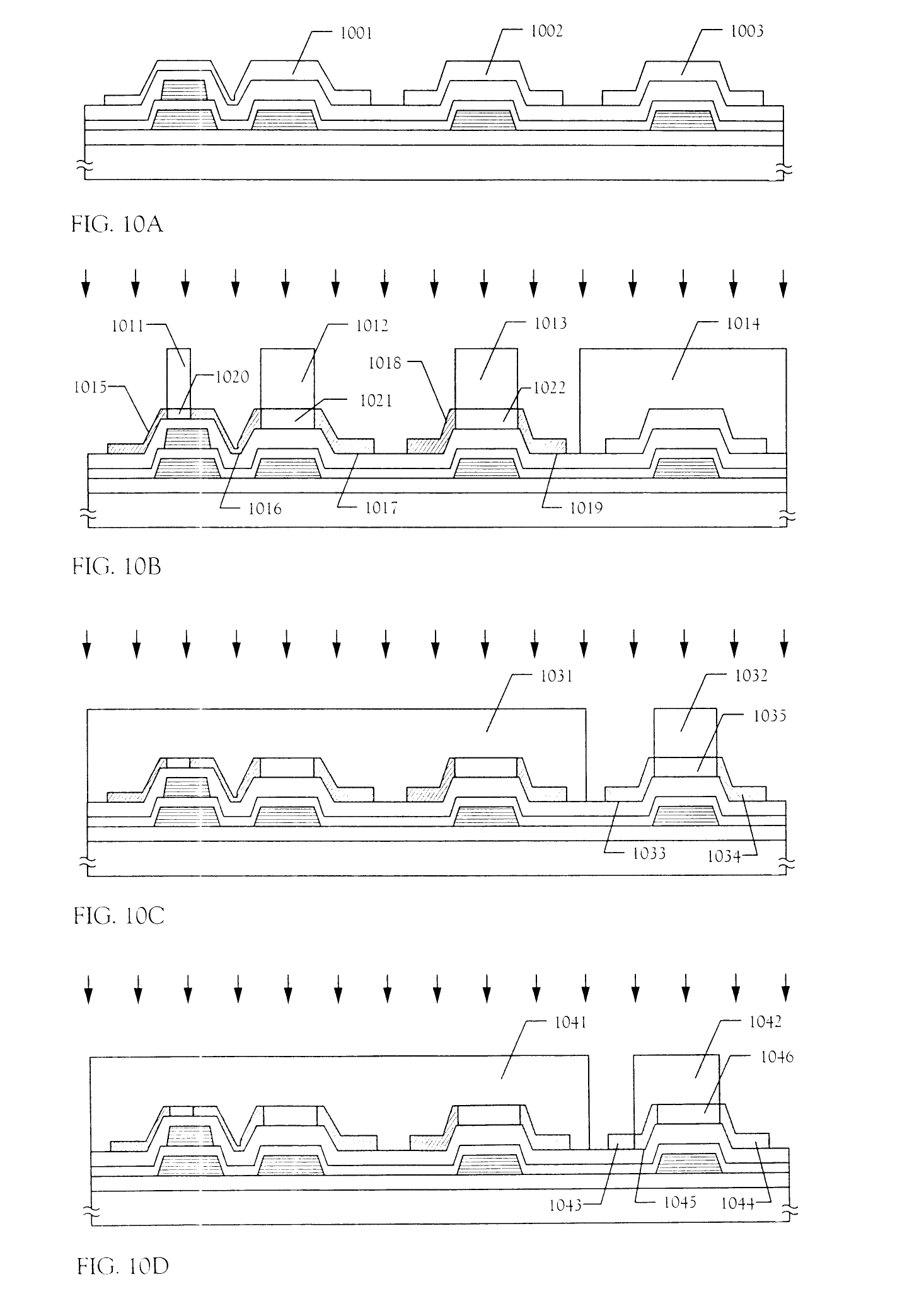

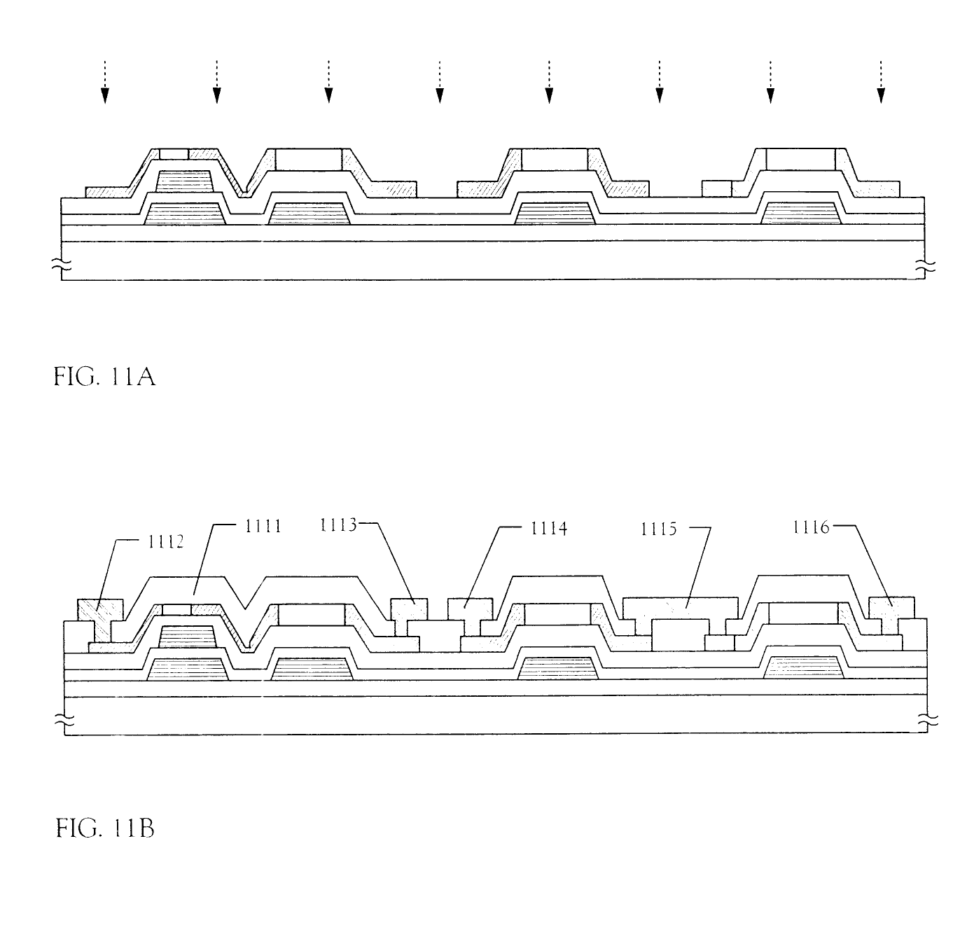

Next, FIGS. 10A to 10D are referred to. First, active layers 1001 to 1003 are formed by patterning the crystalline amorphous films (FIG. 10A).

Next, an impurity element for imparting one conductivity, is added. Phosphorus (P) or arsenic (As) may be used as an n-type impurity, while boron (B), gallium (Ga), indium (In) or the like may be used as a p-type impurity.

After formation of resist masks 1011 to 1014, the impurity element for imparting a p-type conductivity (also referred to as a p-type impurity element) is added (FIG. 10B). As a result, source/drain regions 1015 to 1019 and channel formation regions 1020 to 1022 of the p-channel TFT are formed. In this embodiment, boron is used as the p-type impurity element, and the concentration of boron is controlled to be 1×10²⁰ to 1×10²¹ atoms/cm³ (typically, 2×10¹⁷ to 5×10²⁰ atoms/cm³).

Next, after removal of the resist masks 1011 to 1014, resist masks 1031 and 1032 are formed. Then, an n-type impurity element (phosphorus is used in this embodiment) is added to form low concentration impurity regions 1033 and 1034 containing phosphorus at the concentration of about 1×10¹⁷ to 1×10¹⁹ atoms/cm³ (FIG. 10C).

Then, after removal of the resist masks 1031 and 1032, resist masks 1041 and 1042 are formed. The n-type impurity element is added again at a higher concentration (1×10²⁰ to 1×10²¹ atoms/cm³) than that in the step shown in FIG. 10C so as to form source/drain regions 1043 and 1044 of the n-type TFT. A region 1045 is a low concentration impurity region, and a region 1046 is a channel formation region (FIG. 10D).

Next, after removal of the resist masks 1041 and 1042, excimer laser is irradiated (laser annealing) to repair the damages that are caused on injection of the impurity element and to activate the added impurity (FIG. 11A).

After the completion of laser annealing, an interlayer insulating film 1111 is formed to a thickness of 300 to 500 nm (FIG. 11B). The interlayer insulating film 1111 is made of a silicon oxide film, a silicon nitride film, a silicon nitride oxide film, an organic resin film or a laminate film thereof.

Next, contact holes are formed through the interlayer insulating film 1111 so as to form source/drain electrodes 1112 to 1116 made of a thin metal film. As the thin metal film, aluminum, tantalum, titanium, tungsten, molybdenum, or a laminate film thereof may be used (FIG. 11B).

Finally, a heat treatment is conducted for the entire structure at 350° C. for about two hours in a hydrogen atmosphere so as to terminate a dangling bond in the film (in the channel formation regions, in particular) with hydrogen. By the above step, TFTs having the structure as shown in FIG. 11B can be manufactured.

### [Embodiment 3]

In the cross-sectional view of the memory cell shown in FIG. 2, the semiconductor active layer (thickness: d1) of the memory TFT is thinner than that (thickness: d2) of the switching TFT. However, it is sufficient to form these semiconductor active layers so that d1 is 1 to 100 nm (preferably, 1 to 50 nm, more preferably, 10 to 40 nm) and d2 is 1 to 150 nm (preferably, 10 to 100 nm). Particularly, the semiconductor active layer of the memory TFT and the semiconductor active layer of the switching TFT may have the same thickness.

The semiconductor active layers of TFTs constituting a driver circuit of the memory cells and other peripheral circuits may be formed so as to have the same thickness as that of the semiconductor active layer of the memory TFT or to have a greater thickness than that of semiconductor active layer of the memory TFT as long as a driving frequency of the circuit is not lowered.

For this embodiment, the manufacture methods of Embodiments 1 and 2 can be employed. In such a case, it is not necessary to form semiconductor active layers having different thicknesses. Accordingly, the manufacture process can be simplified.

### [Embodiment 4]

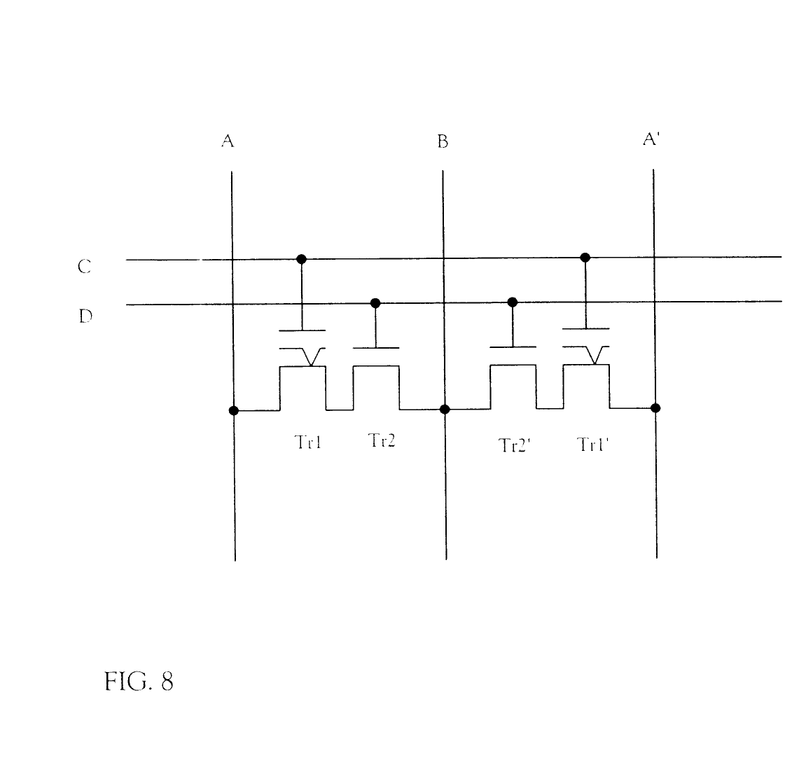

In this embodiment, an example of a circuit diagram of a memory cell different from that of the memory cell in the nonvolatile memory shown in FIG. 1 will be described with reference to FIG. 8. FIG. 8 is a circuit diagram showing two adjacent memory cells arranged in the same row in a memory cell array in which a plurality of memory cells are arranged in matrix. In FIG. 8, two adjacent memory cells share a signal line (referred to as a signal line B) connected to a source electrode of a switching TFT.

More specifically, signal lines A and A are connected to drain electrodes of memory TFTs Tr1 and Tr1 on the right and left, respectively. The signal line B is connected to source electrodes of switching TFT Tr2 and Tr2′. A signal line C is connected to control gate electrodes of the memory TFT Tr1 and Tr1′ whereas a signal line D is connected to gate electrodes of the switching TFTs Tr2 and Tr2′. The two memory cells have such a structure that the memory TFT and the switching TFT are provided in a symmetrical manner with respect to the signal line B.

With such a structure, the number of the signal lines B can be reduced as compared with the structure shown in FIG. 1 so as to allow the memory cells to be arranged at a higher density. As a result, the nonvolatile memory can be reduced in size, or can have an increased capacity.

This embodiment can be combined any structure of Embodiments 1 to 3.

### [Embodiment 5]

In this embodiment, a low-grade quartz substrate at low cost is first prepared. Next, the quartz substrate is polished by a technique such as CMP (chemical mechanical polishing) until the ideal state (the average value of level differences is within 5 nm, typically within 3 nm, preferably within 2 nm) is obtained.

As described above, even a low-cost quartz substrate can be used as an insulating substrate having excellent flatness owing to polishing. Since the quartz substrate forms an extremely fine base, a high stability of the interface between a base and a semiconductor thin film is obtained by the use of the quartz substrate. Moreover, since the effect of contamination due to the substrate is little, the quartz substrate has an extremely high utility value.

This embodiment can be combined with any structure of Embodiments 1 to 4.

### [Embodiment 6]

In Embodiments 1 and 2, the example where an element selected from members of Group 15 (phosphorus in Embodiments 1 and 2) is used in the step of gettering the catalyst element for promoting the crystallization of silicon has been described. In the present invention, it is also possible to use a halogen element in the gettering step of the catalyst element.

In this embodiment, the step of gettering the catalyst element is conducted by using, a treatment atmosphere containing a halogen element, in a heat treatment after the formation of the ,ate insulating film on the semiconductor active layer (see FIG. 5A).

In order to sufficiently obtain the gettering effect of a halogen element, it is preferred to conduct the above heat treatment at a temperature exceeding 700° C. A halogen compound in a treatment temperature hardly decomposes at a temperature of 700° C. or less. As a result, there is a possibility that the gettering effect will not be obtained. Therefore, a heat treatment temperature is preferably set to 800 to 1000° C. (typically, 950° C.), and treatment time is set to 0.1 to 6 hours, typically 0.5 to 1 hour.

As a typical embodiment, a heat treatment may be conducted at 950° C. for 30 minutes in an atmosphere obtained by adding hydrogen chloride (HCl) at 0.5 to 10% by volume (in this embodiment, 3% by volume) to an oxygen atmosphere. The concentration of HCl higher than the above range is not preferable because unevenness nearly corresponding to the thickness of the film occurs on the surfaces of the semiconductor active layers with such a concentration.

In addition to the HCl gas, one or a plurality of compounds containing a halogen element selected from the group consisting of HF, NF₃, HBr, Cl₂, CIF₃, BCl₃, F₂, Br₂ and the like can be used as a compound containing a halogen element.

In this step, nickel in the semiconductor active layer is gettered due to the effect of chlorine, resulting in volatile nickel chloride that is desorbed in the air to be removed. As a result of this step, the concentration of nickel in the semiconductor active layer is reduced to 5×10¹⁷ atoms/cm³ or less (typically, 2×10¹⁷ atoms/cm³ or less). Based on the experience of the inventors of the present invention, TFT properties are not adversely affected as long as a nickel concentration is 1×10¹⁸ atoms/cm³ or less (preferably, 5×10¹⁷ atoms/cm³ or less).

The gettering treatment described above is also effective for metal elements other than nickel. A constituting element (typically, aluminum, iron, chromium, or the like) of a film formation chamber is mainly considered as a metal element that can be mixed in the silicon film. The concentration of these metal elements can be lowered to 5×10¹⁷ atoms/cm³ or less (preferably, 2×10¹⁷ atoms/cm³ or less) by performing the above gettering treatment.

After the above gettering treatment, the halogen element used for the gettering treatment remains in the semiconductor active layer at the concentration of 1×10¹⁶ to 1×10²⁰ atoms/cm³.

Moreover, as the result of the heat treatment, a thermal oxidation reaction proceeds at the interface between the semiconductor active layer and the gate insulating film to increase the thickness of the gate insulating film by the thickness of the thermal oxide film. The formation of the thermal oxide film in this manner allows the interface having an extremely small interface level to be obtained between the semiconductor and the insulating film. In addition, such a formation method is effective for preventing poor formation of the thermal oxide film at the edges of the active layer (edge thinning).

In the manner as described above, the gettering step of the catalyst element using the halogen element is conducted. For the other steps, the manufacture process may be conducted following the process described in Embodiment 1 or 2. As a result, a nonvolatile memory having the same characteristics as those described in Embodiment 1 or 2 can be obtained.

This embodiment can be combined any structure of Embodiments 3 to 5

### [Embodiment 7]

In this embodiment, the case where tantalum (Ta) or a Ta alloy is used for the gate electrode and a thermal oxide film of the gate electrode made of Ta or a Ta alloy is used as an insulating film between a floating gate electrode and a control gate electrode of the memory TFT in accordance with the manufacture method described in Embodiment 1 or 2 will be described.

In the case where the manufacture method described in Embodiment 1 is employed, Ta or a Ta alloy may be used for the floating gate electrode of the memory TFT, and be then subjected to thermal oxidation. In the case where the manufacture method described in Embodiment 2 is employed, Ta or a Ta alloy may be used for the control gate electrode of the memory TFT, and be then subjected to thermal oxidation.

In the case where Ta or a Ta alloy is used for the gate electrode, thermal oxidation can be conducted at about 450° C. to about 600° C., resulting in a high-quality oxide film such as Ta₂O₃ formed on the gate electrode.

A relative dielectric constant of the thus formed insulating film is, in the case of Ta₂O₃ for example, about 11.6, i.e., a relatively great value as compared with that of the insulating film containing silicon. Therefore, in the case where the same thickness is employed a greater amount of the capacitor is formed between the floating gate and the control gate. As a result, the use of the thermal oxide film made of Ta or a Ta alloy allows the manufacture of a nonvolatile memory having such a structure that charges are more likely to be injected to the floating gate as compared with the insulating film containing silicon.

This embodiment can be combined with any structure of Embodiments 3 to 6.

### [Embodiment 8]

The nonvolatile memory of the present invention has various applications. In this embodiment, electro-optical devices (typically, a liquid crystal display device and an EL display device) including the nonvolatile memory according to the present invention as a memory section will be especially described.

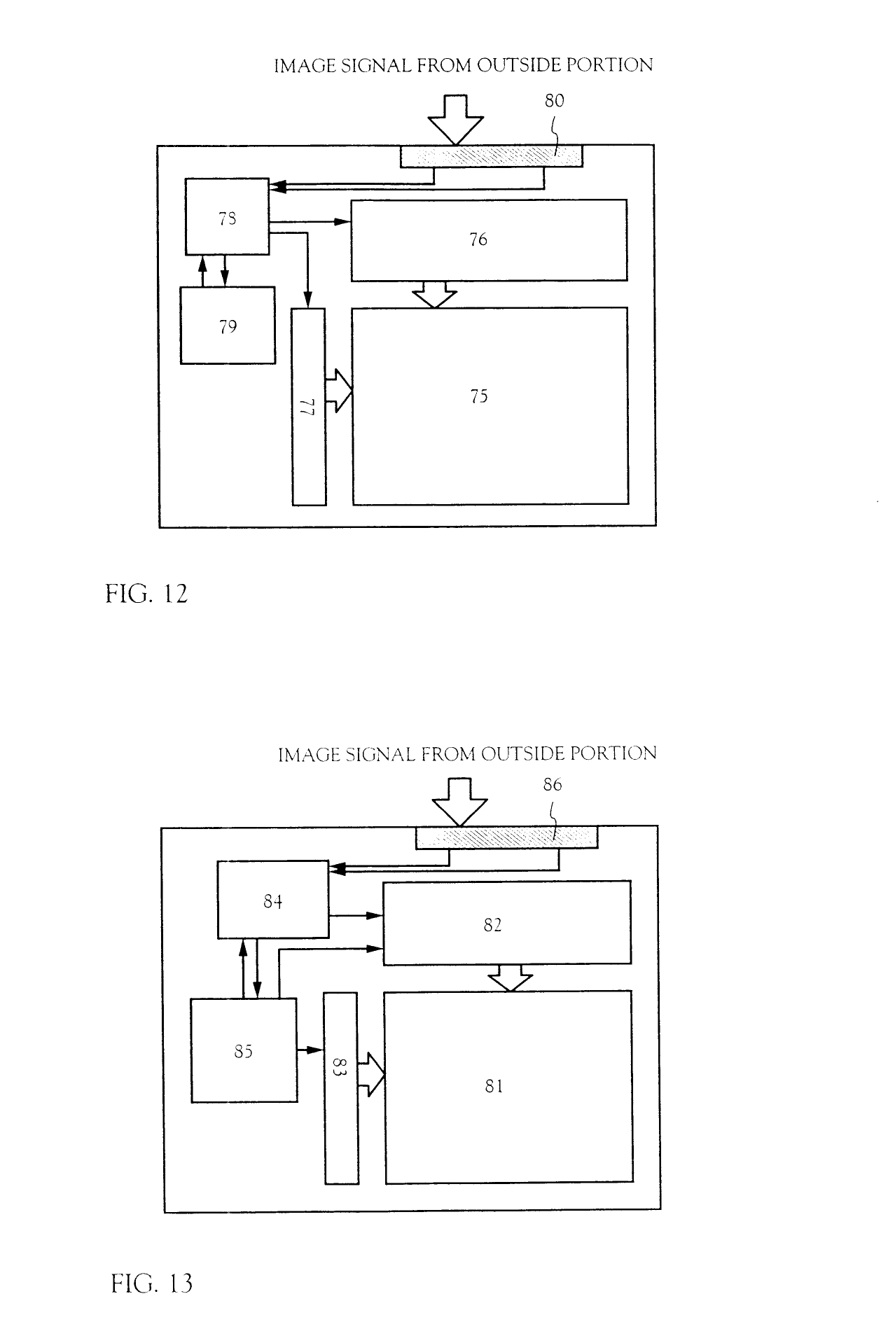

First, an example of an electro-optical device including at least the nonvolatile memory of the present invention, a pixel portion, a driver circuit for driving the pixel portion and a γ (gamma) correction circuit is described with reference to FIG. 12.

The γ correction circuit is for performing γ correction. The γ correction is performed to establish a linear relationship between a voltage applied to the pixel electrode and an intensity of tight transmitted through an overlying liquid crystal or EL layer by adding an appropriate voltage to an image signal.

Although one source wiring driver circuit and one gate wiring driver circuit are provided in this embodiment, a plurality of source wiring driver circuits and gate wiring driver circuits may be provided. For the pixel portion, the driver circuit for driving the pixel portion and the γ correction circuit, a known circuit structure may be used.

The electro-optical device of this embodiment is constituted by TFTs formed on an insulating substrate, and can be manufactured by using the method of manufacturing a nonvolatile memory according to the present invention. For the manufacture steps after the formation of TFTs such as the step of forming a liquid crystal or EL layer, a known manufacture process may be employed.

FIG. 12 is a block diagram of the above-described electro-optical device. A source wiring driver circuit 76 and a gate wiring driver circuit 77 are provided in the periphery of a pixel portion 75. Furthermore, a γ correction circuit 78 and a nonvolatile memory 79 are also provided. An image signal, a clock signal, a synchronizing signal or the like is transmitted via an FPC (Flexible Printed Circuit) 80.

The nonvolatile memory 79 stores (memorizes) correction data for performing, γ correction on an image signal transmitted from a personal computer body, a television receiving antenna or the like. With reference to this correction data, the γ correction circuit 78 performs γ correction on the image signal.

Although it is sufficient to store the data for γ correction once before the shipment of the electro-optical device, it is also possible to periodically rewrite the correction data. Even the electro-optical devices manufactured in the same manner may have slightly different optical response characteristics (such as the above-mentioned relationship between the intensity of transmitted light and the applied voltage). Even in such a case, since different γ correction data can be stored for each electro-optical device in this embodiment, images of the same quality can be constantly obtained.

When the correction data for γ correction is to be stored in the nonvolatile memory 79, it is preferable to use the means described in Japanese Patent Application Serial No. Hei 10-156696 by the applicant of the present invention. This Japanese Patent Application also includes the description about γ correction.

Since the correction data stored in the nonvolatile memory is digital signals, it is desirable to form a D/A converter or an A/D converter on the same substrate as is needed.

Next, an example of the electro-optical device including at least a nonvolatile memory of the present invention, a pixel portion, a driver circuit for driving the pixel portion and a memory controller circuit is described with reference to FIG. 13.

A memory controller circuit in this embodiment is a control circuit for controlling the operation such as storing/reading out the image data in/from the nonvolatile memory.

Although one source wiring driver circuit and one gate wiring driver circuit are provided in this embodiment, a plurality of source wiring driver circuits and gate wiring driver circuits may be provided. For the pixel portion, the driver circuit for driving, the pixel portion and the memory controller circuit, a known circuit structure may he used.

The electro-optical device of this embodiment is constituted by TFTs formed on an insulating substrate, and can be manufactured by using the method of manufacturing the nonvolatile memory of the present invention. For the manufacture steps after the formation of TFTs such as the step of forming a liquid crystal or EL layer, a known manufacture process may be employed.

FIG. 13 is a block diagram of the electro-optical device of this embodiment. A source wiring driver circuit 82 and a gate wiring driver circuit 83 are provided in the periphery, of a pixel portion 81. Furthermore, a memory controller circuit 84 and a nonvolatile memory 85 of the present invention are also provided. An image signal, a clock signal, a synchronizing signal or the like is transmitted via an FPC (Flexible Printed Circuit) 86.

The nonvolatile memory 85 stores (memorizes) an image signal transmitted from a personal computer body, a television receiving antenna or the like for each frame. The image signals are sequentially input to the pixel portion 81 to perform display. The nonvolatile memory 85 stores image information for one frame of the image to be displayed on the pixel portion 81. For example, in the case where a digital signal of 6 bits is transmitted as an image signal, a memory capacity corresponding to the number of pixels×6 bits is required.

Since the correction data stored in the nonvolatile memory is digital signals, it is desirable to form a D/A converter or an A/D converter on the same substrate as is needed.

The images displayed on the pixel portion 81 are constantly stored in the nonvolatile memory 85 with the structure of this embodiment, thereby allowing the operations such as pause of the image with ease. More specifically, the image signals stored in the nonvolatile memory 85 are constantly transmitted to the pixel portion 81 by the memory controller circuit 84, thereby making it possible to pause the television broadcasting as desired without recording it on a video deck or the like.

The example where image information for one frame is stored is described in this embodiment. However, if the memory capacity of the nonvolatile memory 85 is increased to such a degree that the image information for several thousand frames can be stored, not only the pause but also the replay of images displayed several seconds or several minutes before can also be performed.

The structure of this embodiment can be implemented in free combination with any structure of Embodiments 1 to 7.

### [Embodiment 9]

The nonvolatile memory of the present invention has various applications. In this embodiment, electrical devices using the nonvolatile memory will be described.

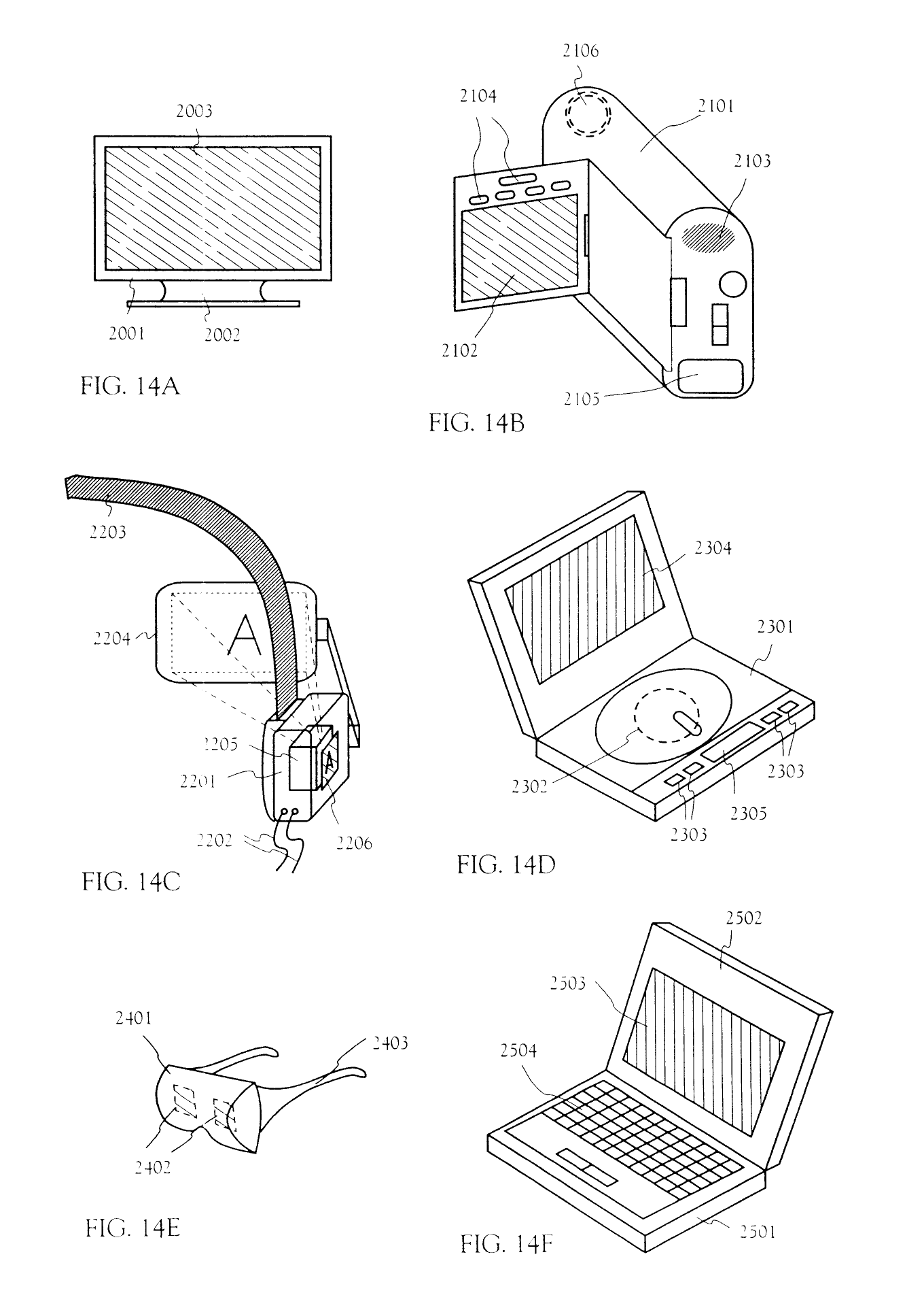

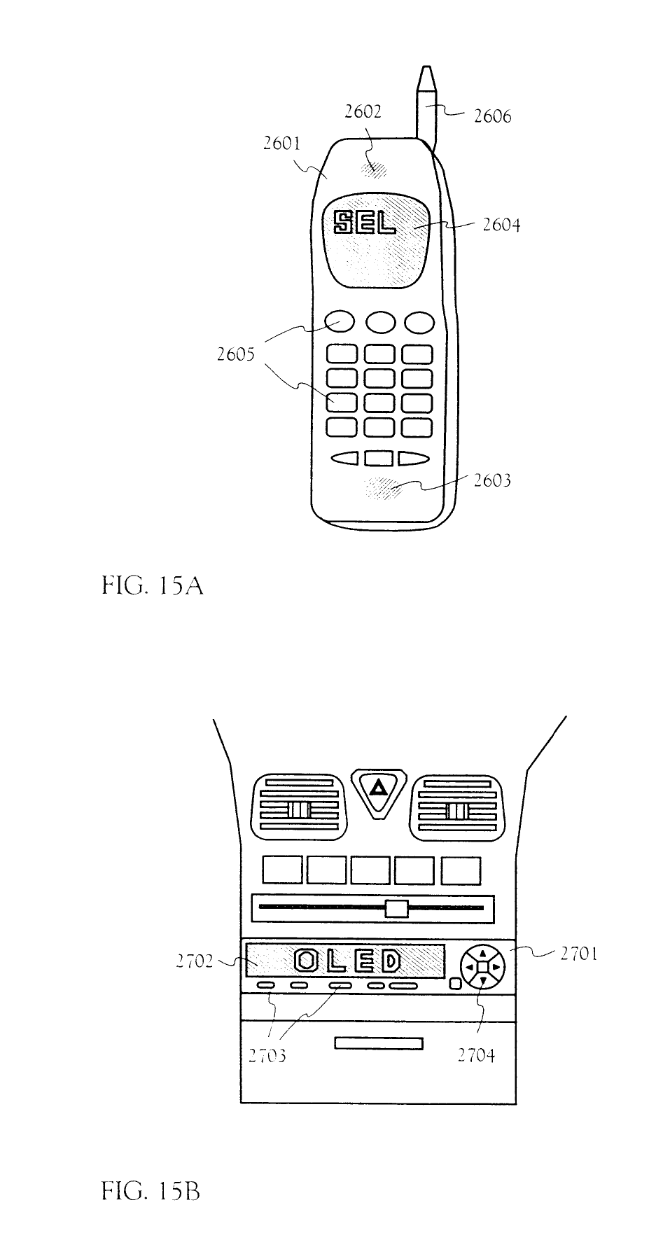

As examples of such electrical devices, video cameras, digital cameras, projectors (rear type or front type), head-mounted displays (goggle type display), game machines, car navigation systems, personal computers, portable information terminals (such as a mobile computer, a portable telephone, or an electric book) and a DVD player can be given. Some examples of these electrical devices are shown in FIGS. 14A to 15B.

FIG. 14A illustrates a display including a box-shaped body 2001, a support 2002, a display portion 2003 and the like. The nonvolatile memory of the present invention may be integrally formed with the display portion 2003 or other signal control circuits.

FIG. 14B illustrates a video camera including a main body 2101, a display portion 2102, a voice input section 2103, operation switches 2104, a battery 2105 and an image-receiving section 2106. The nonvolatile memory of the present invention may tie integrally formed with the display portion 2102 or other signal control circuits.

FIG. 14C illustrates a part (the right half) of a head-mounted type display including a main body 2201, signal cables 2202, a head-fixing band 2203, a display portion 2204, an optical system 2205, a display portion 2206, and the like. The nonvolatile memory of the present invention may be integrally formed with the display portion 2206 or other signal control circuits.

FIG. 14D illustrates an image reproduction device having a recording, medium (specifically, a DVD reproduction device). This image reproduction device includes a main body 2301, a recording medium 2302, operation switches 2303, display portions 2304 and 2305 and the like. This device uses a DVD (Digital Versatile Disc), a CD or the like as a recording medium, thereby allowing music, movies, games and the Internet to be enjoyed. The nonvolatile memory of the present invention may be integrally formed with the display portion 2304 or other signal control circuits.

FIG. 14E illustrates a goggle type display (head-mounted display) including a main body 2401, display portions 2402, and arm portions 2403. The nonvolatile memory of the present invention may be integrally formed with the display portions 2402 or other signal control circuits.

FIG. 14F illustrates a personal computer including a main body 2501, a box-shaped body 2502, a display portion 2503, keyboards 2504 and the like. The nonvolatile memory of the present invention may be integrally formed with the display portion 2503 or other signal control circuits.

FIG. 15A illustrates a portable telephone including a main body 2601, a voice output section 2602, a voice input section 2603, a display portion 2604, operation switches 2605, and an antenna 2606. The nonvolatile memory of the present invention may be integrally formed with the display portion 2604 or other signal control circuits.

FIG. 15B illustrates an audio reproduction device, more specifically, a car audio, including a main body 2701, a display portion 2702 and operation switches 2703 and 2704. The nonvolatile memory of the present invention may be integrally formed with the display portion 2702 or other signal control circuits. Although the vehicle-mounted audio is shown in this embodiment, this device may be used for a portable audio reproduction device or an audio reproduction device for domestic use.

As described above, the present invention has an extremely wide application, and therefore is applicable to electric appliances of various fields. The electric appliances in this embodiment can be realized using the structure obtained by any combination of Embodiments 1 to 8.

According to the present invention, a nonvolatile memory can be integrally formed with its driver circuit and other peripheral circuits on the insulating substrate, thereby allowing the reduction of the nonvolatile memory in size. -Moreover, according to the present invention, since the memory TFT and the switching TFT are formed on the same semiconductor active layer in each of the memory cells constituting the nonvolatile memory, the nonvolatile memory can be reduced in size.

Furthermore, according to the present invention, since the thickness of the semiconductor active layer of the nonvolatile memory is relatively thin, impact ionization is likely to occur. As a result, a nonvolatile memory driven at a low voltage with little degradation is realized.

Furthermore, the nonvolatile memory of the present invention is integrally formed with an arbitrary circuit constituted by TFTs on the insulating substrate, thereby allowing the reduction of a semiconductor device including the nonvolatile memory in size.

What is claimed is:

1. A nonvolatile memory comprising:
a memory cell array including a plurality of memory cells being, formed in a matrix;
each of the memory cells including a memory thin film transistor and a switching thin film transistor;
said memory thin film transistor including:
a first semiconductor active layer over an insulating substrate;
a first insulating film;
a floating gate electrode;
a second insulating film;
a control gate electrode;
said switching thin film transistor including:
a second semiconductor active layer over the insulating substrate;
a gate insulating film;
a gate electrode,
wherein the memory thin film transistor and the switching thin film transistor are integrally formed over the insulating substrate,
wherein the first semiconductor active layer of the memory thin film transistor and the second semiconductor active layer are continuously formed,
wherein a first thickness of the first semiconductor active layer of the memory thin film transistor is thinner than a second thickness of the second semiconductor active layer of the switching thin film transistor.

2. A memory according to claim 1,
wherein each of the first and second thicknesses is in a range of 1-150 nm.

3. A nonvolatile memory comprising:
a memory cell array including a plurality of memory cells being formed in a matrix;
each of the memory cells including a memory thin film transistor and a switching thin film transistor;
said memory thin film transistor including:
a first semiconductor active layer over an insulating substrate;
a first insulating film;
a floating gate electrode;
a second insulating film;
a control gate electrode;
said switching thin film transistor including:
a second semiconductor active layer over the insulating substrate;
a gate insulating film;
a gate electrode,
wherein the memory thin film transistor and the switching thin film transistor are integrally formed over the insulating substrate,
wherein the first semiconductor active layer of the memory thin film transistor and the second semiconductor active layer are continuously formed,
wherein a first thickness of the first semiconductor active layer of the memory thin film transistor is in a range of 1-100 nm while a second thickness of the second semiconductor active layer of the switching thin film transistor is in a range of 1-150 nm.

4. A memory according to claim 1,
wherein the first thickness in a range of 1-50 nm while the second thickness is in a range of 10-100 nm.

5. A memory according to claim 4,
wherein the first thickness is in a range of 10-40 nm.

6. A memory according to claim 1,
wherein the first thickness of the first semiconductor active layer of the memory thin film transistor is more likely to cause impact ionization than the second thickness of the second semiconductor active layer.

7. A memory according to claim 1,
wherein a first tunnel current flowing between the floating gate electrode and the first semiconductor active layer of the memory thin film transistor is twice or more of a second tunnel current flowing between the gate electrode and the second semiconductor active layer of the switching thin film transistor.

8. A memory according to claim 1,
wherein each of the memory thin film transistor and the switching thin film transistor is a p-channel thin film transistor.

9. A memory according, to claim 1, further comprising a driver circuit for driving the plurality of memory cells,
wherein the memory cell array and the driver circuit are integrally formed over the insulating substrate.

10. A semiconductor device including the nonvolatile memory of claim 1, said semiconductor device further comprising
a pixel portion;
a driver circuit for driving the pixel portion,
wherein the pixel portion, the driver portion and the nonvolatile memory are integrally formed over the insulating substrate.

11. A device according to claim 10,
wherein the semiconductor device is one selected from the group consisting of a liquid crystal display device and an EL display device.

12. A device according to claim 10,
wherein the semiconductor device is one selected from the group consisting of a display, a video camera, a head-mounted type display, a DVD display, a goggle type display, a personal computer, a portable telephone, and a car audio.

13. A method of manufacturing a nonvolatile memory,
said nonvolatile memory including a memory cell array having a plurality of memory cells being formed in a matrix,
each of said plurality of memory cells including a memory thin film transistor and a switching thin film transistor,
said method comprising the steps of:
forming a first amorphous semiconductor layer and a second amorphous semiconductor layer over an insulating substrate;
crystallizing the first amorphous semiconductor layer and the second amorphous semiconductor layer to form a crystalline semiconductor layer having a first region with a first thickness and a second region with a second thickness;
forming the memory thin film transistor including the first region with the first thickness as a first semiconductor active layer;
forming the switching thin film transistor including the second region with the second thickness as a second semiconductor active layer,
wherein the first thickness is thinner than the second thickness.

14. A method according to claim 13,
wherein each of the first and second thicknesses is in a range of 1-150 nm.

15. A method of manufacturing a nonvolatile memory,
said nonvolatile memory including a memory cell array having a plurality of memory cells being formed in a matrix,
each of said plurality of memory cells including a memory thin film transistor and a switching thin film transistor,
said method comprising the steps of:
forming a first amorphous semiconductor layer and a second amorphous semiconductor layer over an insulating substrate;
crystallizing the first amorphous semiconductor layer and the second amorphous semiconductor layer to form a crystalline semiconductor layer having a first region with a first thickness and a second region with a second thickness;
forming the memory thin film transistor including the first region with the first thickness as a first semiconductor active layer;
forming the switching thin film transistor including the second region with the second thickness as a second semiconductor active layer,
wherein a first thickness of the first semiconductor active layer of the memory thin film transistor is in a range of 1-100 nm while a second thickness of the second semiconductor active layer of the switching thin film transistor is in a range of 1-150 nm.

16. A method according to claim 13,
wherein the first thickness in a range of 1-50 nm while the second thickness is in a range of 10-100 nm.

17. A method according to claim 16,
wherein the first thickness is in a range of 10-40 nm.

18. A method according to claim 13,
wherein the first thickness of the first semiconductor active layer of the memory thin film transistor is more likely to cause impact ionization than the second thickness of the second semiconductor active layer.

19. A method according to claim 13,
wherein a first tunnel current flowing between the floating gate electrode and the first semiconductor active layer of the memory thin film transistor is twice or more of a second tunnel current flowing between the gate electrode and the second semiconductor active layer of the switching thin film transistor.

20. A method according to claim 13,
wherein each of the memory thin film transistor and the switching thin film transistor is a p-channel thin film transistor.

21. A method according to claim 13,
wherein the nonvolatile memory further comprises a driver circuit for driving the plurality of memory cells,
wherein the memory cell array and the driver circuit are integrally formed over the insulating substrate.

22. A method of fabricating a semiconductor device including the nonvolatile memory being manufactured by the method of claim 13,
said semiconductor device further comprising:
a pixel portion;
a driver circuit for driving the pixel portion;
wherein the pixel portion, the driver portion and the nonvolatile memory are integrally formed over the insulating substrate.

23. A method according to claim 22,
wherein the semiconductor device is one selected from the group consisting of a liquid crystal display device and an EL display device.

24. A method according to claim 22,
wherein the semiconductor device is one selected from the group consisting of a display, a video camera, a head-mounted type display, a DVD display, a goggle type display, a personal computer, a portable telephone, and a car audio.

25. A method according to claim 15,
wherein the first thickness in a range of 1-50 nm while the second thickness is in a range of 10-100 nm.

26. A method according to claim 25,
wherein the first thickness is in a range of 10-40 nm.

27. A method according to claim 15,
wherein the first thickness of the first semiconductor active layer of the memory thin film transistor is more likely to cause impact ionization than the second thickness of the second semiconductor active layer.

28. A method according to claim 15,
wherein a first tunnel current flowing between the floating gate electrode and the first semiconductor active layer of the memory thin film transistor is twice or more of a second tunnel current flowing between the gate electrode and the second semiconductor active layer of the switching thin film transistor.

29. A method according to claim 15,
wherein each of the memory thin film transistor and the switching thin film transistor is a p-channel thin film transistor.

30. A method according to claim 15,
wherein the nonvolatile memory further comprises a driver circuit for driving the plurality of memory cells,
wherein the memory cell array and the driver circuit are integrally formed over the insulating substrate.

31. A method of fabricating a semiconductor device including the nonvolatile memory being manufactured by the method of claim 15,
said semiconductor device further comprising:
a pixel portion;
a driver circuit for driving the pixel portion;
wherein the pixel portion, the driver portion and the nonvolatile memory are integrally formed over the insulating substrate.

32. A method according to claim 31,
wherein the semiconductor device is one selected from the group consisting of a liquid crystal display device and an EL display device.

33. A method according to claim 31,
wherein the semiconductor device is one selected from the group consisting of a display, a video camera, a head-mounted type display, a DVD display, a goggle type display, a personal computer, a portable telephone, and a car audio.

34. A memory according to claim 3,
wherein the first thickness in a range of 1-50 nm while the second thickness is in a range of 10-100 nm.

35. A memory according to claim 34,
wherein the first thickness is in a range of 10-40 nmn.

36. A memory according to claim 3,
wherein the first thickness of the first semiconductor active layer of the memory thin film transistor is more likely to cause impact ionization than the second thickness of the second semiconductor active layer.

37. A memory according to claim 3,
wherein a first tunnel current flowing between the floating gate electrode and the first semiconductor active layer of the memory thin film transistor is twice or more of a second tunnel current flowing between the gate electrode and the second semiconductor active layer of the switching, thin film transistor.

38. A memory according to claim 3,
wherein each of the memory thin film transistor and the switching thin film transistor is a p-channel thin film transistor.

39. A memory according to claim 3, further comprising a driver circuit for driving the plurality of memory cells,
wherein the memory cell array and the driver circuit are integrally formed over the insulating substrate.

40. A semiconductor device including, the nonvolatile memory of claim 3, said semiconductor device further comprising:
a pixel portion;
a driver circuit for driving the pixel portion,
wherein the pixel portion, the driver portion and the nonvolatile memory are integrally formed over the insulating substrate.

41. A device according to claim 40,
wherein the semiconductor device is one selected from the group consisting of a liquid crystal display, device and an EL display device.

42. A device according to claim 40,
wherein the semiconductor device is one selected from the group consisting of a display, a video camera, a head-mounted type display, a DVD display, a goggle type display, a personal computer, a portable telephone, and a car audio.
